(19) United States
(12) Patent Application Publication
(10) Pub. No.: US 2020/0117087 A1
(43) Pub. Date: Apr. 16, 2020

(54) RADIATION-SENSITIVE RESIN COMPOSITION AND RESIST PATTERN-FORMING METHOD

(71) Applicant: JSR CORPORATION, Tokyo (JP)

(72) Inventor: Tetsurou KANEKO, Tokyo (JP)

(73) Assignee: JSR CORPORATION, Tokyo (JP)

(21) Appl. No.: 16/713,471

(22) Filed: Dec. 13, 2019

Related U.S. Application Data
(63) Continuation of application No. PCT/JP2018/020600, filed on May 29, 2018.

(30) Foreign Application Priority Data
Jun. 15, 2017 (JP) 2017-118136

(51) Int. Cl. G03F 7/039; G03F 7/004

(52) U.S. Cl. CPC G03F 7/039; G03F 7/162; G03F 7/0045

(57) ABSTRACT

A radiation-sensitive resin composition contains: a first polymer including a first structural unit that includes a phenolic hydroxy group, and a second structural unit that includes an acid-labile group; a second polymer including a fluorine atom, a silicon atom, or both, and including a third structural unit that includes an alkali-labile group; a first compound that generates upon an irradiation with a radioactive ray an acid capable of dissociating the acid-labile group within 1 minute under a temperature T^{X}° C. of no less than 80° C. and no greater than 130° C.; and a second compound that generates upon an irradiation with a radioactive ray a carboxylic acid, a sulfonic acid, or both, the carboxylic acid and the sulfonic acid each being not capable of substantially dissociating the acid-labile group within 1 minute under the temperature T^{X}° C.

### CROSS-REFERENCE TO RELATED APPLICATIONS

The present application is a continuation application of International Application No. PCT/JP2018/020600, filed May 29, 2018, which claims priority to Japanese Patent Application No. 2017-118136, filed Jun. 15, 2017. The contents of these applications are incorporated herein by reference in their entirety.

### BACKGROUND OF THE INVENTION

### Field of the Invention

The present invention relates to a radiation-sensitive resin composition and a resist pattern-forming method.

### Discussion of the Background

A radiation-sensitive composition for use in microfabrication by lithography generates an acid at a light-exposed region upon an irradiation with a radioactive ray, e.g., an electromagnetic wave such as a far ultraviolet ray such as an ArF excimer laser beam, a KrF excimer laser beam, etc., an extreme ultraviolet ray (EUV), or a charged particle ray such as an electron beam. A chemical reaction in which the acid serves as a catalyst causes a difference in rates of dissolution in a developer solution, between light-exposed regions and light-unexposed regions, whereby a resist pattern is formed on a substrate.

Such a radiation-sensitive composition is demanded to be superior in not only resolution and rectangularity of the cross-sectional shape of the resist pattern but also in a LWR (Line Width Roughness) performance as well as a depth of focus, thereby enabling a highly accurate pattern to be obtained with high process yield. To address the demands, the structure of the polymer contained in the radiation-sensitive resin composition has been extensively studied, and it is known that incorporation of a lactone structure such as a butyrolactone structure or a norbornanelactone structure can serve to enhance the adhesiveness of the resist pattern to the substrate and improve the aforementioned performances (see Japanese Unexamined Patent Application, Publication Nos. H11-212265, 2003-5375 and 2008-83370).

### SUMMARY OF THE INVENTION

According to an aspect of the present invention, a radiation-sensitive resin composition contains: a first polymer including a first structural unit that includes a phenolic hydroxy group, and a second structural unit that includes an acid-labile group; a second polymer including a fluorine atom, a silicon atom, or both, and including a third structural unit that includes an alkali-labile group; a first compound that generates upon an irradiation with a radioactive ray an acid capable of dissociating the acid-labile group within 1 minute under a temperature T^{X}° C. of no less than 80° C. and no greater than 130° C.; and a second compound that generates upon an irradiation with a radioactive ray a carboxylic acid, a sulfonic acid, or both, the carboxylic acid and the sulfonic acid each being not capable of substantially dissociating the acid-labile group within 1 minute under the temperature T^{X}° C.

According to another aspect of the present invention, a resist pattern-forming method includes applying the radiation-sensitive resin composition directly or indirectly on at least one face side of a substrate to form a resist film. The resist film is exposed to an extreme ultraviolet ray or an electron beam. The resist film exposed is developed.

### DESCRIPTION OF THE EMBODIMENTS

According to a first embodiment of the invention, a radiation-sensitive resin composition contains a first polymer (hereinafter, may be also referred to as “(A1) polymer” or “polymer (A1)”) having a first structural unit (hereinafter, may be also referred to as “structural unit (I)”) that includes a phenolic hydroxy group, and a second structural unit (hereinafter, may be also referred to as “structural unit (II)”) that includes an acid-labile group (hereinafter, may be also referred to as “acid-labile group (a)”); a second polymer (hereinafter, may be also referred to as “(A2) polymer” or “polymer (A2)”) having at least one of a fluorine atom and a silicon atom, and having a third structural unit (hereinafter, may be also referred to as “structural unit (III)”) that includes an alkali-labile group (hereinafter, may be also referred to as “alkali-labile group (b)”); a first compound (hereinafter, may be also referred to as “(B1) compound” or “compound (B1)”) that generates upon an irradiation with a radioactive ray an acid capable of dissociating the acid-labile group (a) under a condition involving a temperature T^{X}° C. of no less than 80° C. and no greater than 130° C. and 1 min; and a second compound (hereinafter, may be also referred to as “(B2) compound” or “compound (B2)”) that generates upon an irradiation with a radioactive ray a carboxylic acid not capable of substantially dissociating the acid-labile group (a) under a condition involving the temperature T^{X}° C. for 1 min, a sulfonic acid not capable of substantially dissociating the acid-labile group (a) under a condition involving the temperature T^{X}° C. for 1 min, or a combination thereof.

According to a second embodiment of the present invention, a resist pattern-forming method includes: applying the radiation-sensitive resin composition according to the one embodiment of the invention directly or indirectly on at least one face side of a substrate; exposing a resist film formed by the applying to an extreme ultraviolet ray or an electron beam; and developing the resist film exposed.

The “acid-labile group” as referred to herein means a group that substitutes for a hydrogen atom of a carboxy group, a phenolic hydroxy group or the like, and is dissociable by an action of an acid. The “alkali-labile group” as referred to herein means a group that substitutes for a hydrogen atom of a carboxy group, an alcoholic hydroxy group or the like and is dissociable in a 2.38% by mass aqueous tetramethylammonium hydroxide solution at 23° C. for 1 min. The number of “ring atoms” as referred to herein means the number of atoms constituting the ring in an alicyclic structure, an aromatic ring structure, an aliphatic heterocyclic structure or an aromatic heterocyclic structure, and in the case of a polycyclic ring structure, the number of “ring atoms” means the number of atoms constituting the polycyclic ring.

The radiation-sensitive resin composition and the resist pattern-forming method of the embodiments of the present invention enable a resist pattern to be formed with less LWR, high resolution, superior rectangularity of the cross-sectional shape, and fewer defects, and high CDU (Critical Dimension Uniformity) performance, by virtue of an extensive exposure latitude. Therefore, these can be suitably used in the manufacture of semiconductor devices in which further progress of miniaturization is expected in the future.

### Radiation-Sensitive Resin Composition

A radiation-sensitive resin composition of a first embodiment of the present invention contains the polymer (A1), the polymer (A2), the compound (B1), and the compound (B2). The radiation-sensitive resin composition may contain (C) a solvent as a favorable component, and may also contain other optional component(s), within a range not leading to impairment of the effects of the present invention.

Due to components (A1), (A2), (B1) and (B2) being contained, the radiation-sensitive resin composition results in superiority with regard to: LWR performance, resolution, rectangularity of the cross-sectional shape, exposure latitude, an inhibitory ability of defects and CDU performance (hereinafter, may be collectively referred to as “lithography characteristics”). Although not necessarily clarified and without wishing to be bound by any theory, the reason for achieving the aforementioned effects by the radiation-sensitive resin composition due to involving such a constitution may be presumed, for example, as in the following. By virtue of the features that: the polymer (A1) for forming the resist film has the structural unit (I) that includes the phenolic hydroxy group, in addition to the structural unit (II) that includes the acid-labile group; and that the polymer (A2) that localizes in the surface layer of the resist film has the structural unit (III) that includes the alkali-labile group, it is considered that hydrophilization of the surface layer of the resist film can be promoted, and as a result, the inhibitory ability of defects is improved. It is assumed that by adjusting the basicity of the compound (B2) to be no greater than a certain level, LWR performance, resolution and CDU performance can each be achieved to a superior level, and storage stability of the radiation-sensitive resin composition is also improved. Each component will be described below.

### (A1) Polymer

The polymer (A1) has the structural unit (1) and the structural unit (II). In addition to the structural units (I) and (II), the polymer (A1) may have a fourth structural unit (hereinafter, may be also referred to as “structural unit (IV)”) including a lactone structure, a cyclic carbonate structure, a sultone structure or a combination thereof, and a fifth structural unit (hereinafter, may be also referred to as “structural unit (V)”) including an alcoholic hydroxy group, as well as structural units other than these structural units (other structural units). The polymer (A1) may include one, or two or more types of each structural unit.

Each structural unit will be described below.

Structural Unit (I) The structural unit (I) includes a phenolic hydroxy group (hereinafter, may be also referred to as “group (I)”). Since the polymer (A1) has the structural unit (I), the resist film can have further increased hydrophilicity. In addition, solubility in the developer solution can be more appropriately adjusted, and the adhesiveness of the resist pattern to the substrate can be further improved. Moreover, in the case of exposure to KrF, EUV or an electron beam, further improved sensitivity of the radiation-sensitive resin composition can be attained. It is to be noted that as referred to herein the “phenolic hydroxy group” is not limited to one directly linked to the benzene ring, and generally means any hydroxy group directly linked to the aromatic ring.

Examples of the group (I) include a group represented by the following formula (3) and the like.

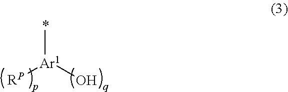

In the above formula (3), Ar¹ represents a group obtained from an arene having 6 to 20 carbon atoms by removing (p+q+1) hydrogen atoms on the aromatic ring; R^{P} represents a halogen atom or a monovalent organic group having 1 to 20 carbon atoms; p is an integer of 0 to 11; q is an integer of 1 to 11; (p+q) is no greater than 11, wherein in a case in which p is no less than 2, a plurality of R^{P}s are identical or different; and * denotes a binding site to a portion other than the group (I) in the structural unit (I).

Examples of the arene having 6 to 20 carbon atoms that gives Ar¹ include benzene, naphthalene, anthracene, phenanthrene, tetracene, pyrene, and the like. Of these, benzene or naphthalene is preferred.

The “organic group” as referred to herein means a group that includes at least one carbon atom. The monovalent organic group having 1 to 20 carbon atoms represented by R^{P} is exemplified by: a monovalent hydrocarbon group having 1 to 20 carbon atoms; a group (α) that includes a divalent hetero atom-containing group between two adjacent carbon atoms or at the end of the atomic bonding side of the monovalent hydrocarbon group having 1 to 20 carbon atoms; a group obtained by substituting a part or all of hydrogen atoms of the monovalent hetero atom-containing group included in the monovalent hydrocarbon group or the group (α); and the like.

The monovalent hydrocarbon group having 1 to 20 carbon atoms is exemplified by a monovalent chain hydrocarbon group having 1 to 20 carbon atoms, a monovalent alicyclic hydrocarbon group having 3 to 20 carbon atoms, a monovalent aromatic hydrocarbon group having 6 to 20 carbon atoms, and the like.

The “hydrocarbon group” may involve a chain hydrocarbon group, an alicyclic hydrocarbon group and an aromatic hydrocarbon group. The “hydrocarbon group” may be a saturated hydrocarbon group or an unsaturated hydrocarbon group. The “chain hydrocarbon group” as referred to herein means a hydrocarbon group not having a ring structure but being constituted only from a chain structure, and involves both a linear hydrocarbon group and a branched hydrocarbon group. The “alicyclic hydrocarbon group” as referred to herein means a hydrocarbon group having as a ring structure not an aromatic ring structure but only an alicyclic structure, and involves both a monocyclic alicyclic hydrocarbon group and a polycyclic alicyclic hydrocarbon group. It is not necessary that the alicyclic hydrocarbon group is constituted from only the alicyclic structure, and a part thereof may also include a chain structure. The “aromatic hydrocarbon group” as referred to herein means a hydrocarbon group that includes an aromatic ring structure as the ring structure. It is not necessary that the aromatic hydrocarbon group is constituted from only the aromatic ring structure, and a part thereof may also include a chain structure and/or an alicyclic structure.

Examples of the monovalent chain hydrocarbon group having 1 to 20 carbon atoms include:

alkyl groups such as a methyl group, an ethyl group, a n-propyl group and an i-propyl group;

alkenyl groups such as an ethenyl group, a propenyl group and a butenyl group;

alkynyl groups such as an ethynyl group, a propynyl group and a butynyl group; and the like.

Examples of the monovalent alicyclic hydrocarbon group having 3 to 20 carbon atoms include:

monocyclic alicyclic saturated hydrocarbon groups such as a cyclopentyl group and a cyclohexyl group;

monocyclic alicyclic unsaturated hydrocarbon groups such as a cyclopentenyl group and a cyclohexenyl group;

polycyclic alicyclic saturated hydrocarbon groups such as a norbornyl group, an adamantyl group and a tricyclodecyl group;

polycyclic alicyclic unsaturated hydrocarbon groups such as a norbornenyl group and a tricyclodecenyl group; and the like.

Examples of the monovalent aromatic hydrocarbon group having 6 to 20 carbon atoms include:

aryl groups such as a phenyl group, a tolyl group, a xylyl group, a naphthyl group and an anthryl group;

aralkyl groups such as a benzyl group, a phenethyl group, a naphthylmethyl group and an anthrylmethyl group; and the like.

The hetero atom that may constitute the monovalent or divalent hetero atom-containing group is exemplified by an oxygen atom, a nitrogen atom, a sulfur atom, a phosphorus atom, a silicon atom, a halogen atom and the like. Examples of the halogen atom include a fluorine atom, a chlorine atom, a bromine atom, an iodine atom and the like.

Examples of the divalent hetero atom-containing group include —O—, —CO—, —S—, —CS—, —NR′—, groups obtained by combining at least two of the aforementioned groups, and the like, wherein R′ represents a hydrogen atom or a monovalent hydrocarbon group.

Examples of the monovalent hetero atom-containing group include: halogen atoms such as a fluorine atom, a chlorine atom, a bromine atom and an iodine atom; a hydroxy group; a carboxy group; a cyano group; an amino group; a sulfanyl group; and the like.

Examples of the structural unit (I) include a structural unit represented by the following formula (3A) (hereinafter, may be also referred to as “structural unit (I-1)”) and the like.

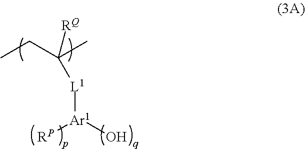

In the above formula (3A), Ar¹, R^{P}, p and q are as defined in the above formula (3); L¹ represents a single bond, an oxygen atom or a divalent organic group having 1 to 20 carbon atoms; and R^{Q} represents a hydrogen atom, a fluorine atom, a methyl group or a trifluoromethyl group.

R^{Q} represents preferably a hydrogen atom or a methyl group, in light of a degree of copolymerization of a monomer that gives the structural unit (I-1).

Examples of the divalent organic group having 1 to 20 carbon atoms which may be represented by L¹ include the groups obtained by removing one hydrogen atom from the monovalent organic groups exemplified as R^{P} in the above formula (3), and the like.

L¹ represents a single bond, an oxygen atom, —COO— or —CONH—, and more preferably a single bond or —COO—.

Examples of the structural unit (I-1) include structural units represented by the following formulae (3A-1) to (3A-8) (hereinafter, may be also referred to as “structural units (I-1-1) to (I-1-8)”), and the like.

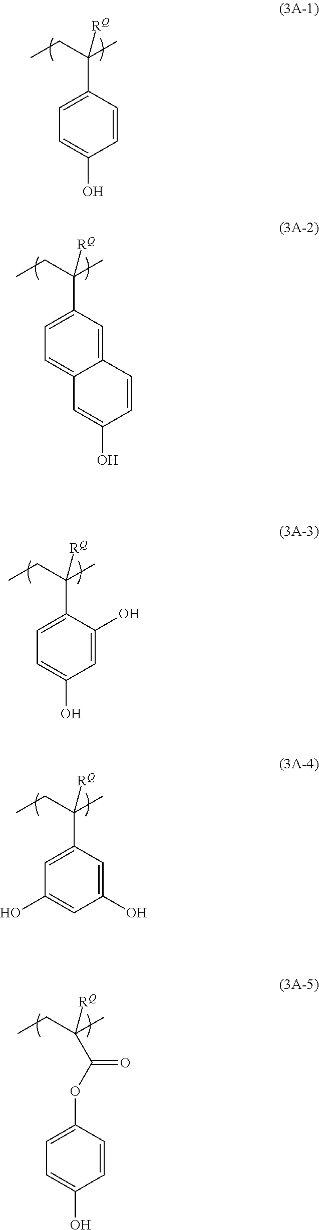

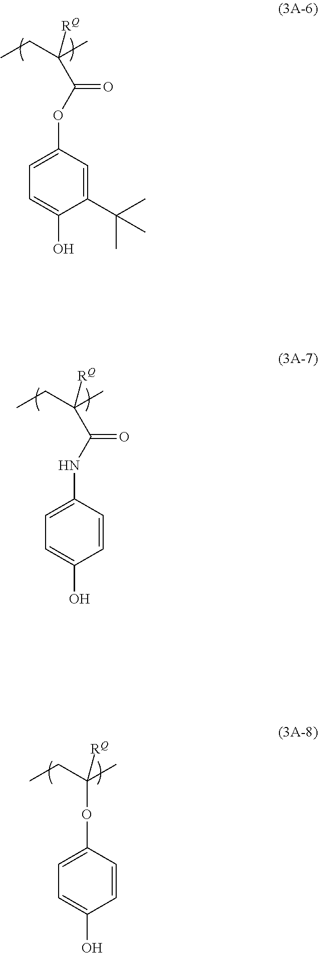

In the above formulae (3A-1) to (3A-8), R^{Q} is as defined in the above formula (3A).

Of these, the structural unit (I-1-1), (I-1-2), (I-1-5) or (A-1-6) is preferred.

The lower limit of the proportion of the structural unit (I) contained with respect to the total structural units constituting the polymer (A1) is preferably 10 mol %, more preferably 25 mol %, and still more preferably 35 mol %. The upper limit of the proportion of the structural unit (I) is preferably 80 mol %, more preferably 70 mol %, and still more preferably 60 mol %. When the proportion of the structural unit (I) falls within the above range, the lithography characteristics of the radiation-sensitive resin composition can be further improved. Moreover, sensitivity in the case of an exposure to KrF, EUV or an electron beam can be further enhanced.

Structural Unit (II)

The structural unit (II) includes the acid-labile group (a). Since the polymer (A1) has the structural unit (II), improved sensitivity of the radiation-sensitive resin composition can be attained.

Examples of the acid-labile group (a) include a group represented by the following formula (2-1) (hereinafter, may be also referred to as “group (II-1)”), a group represented by the following formula (2-2) (hereinafter, may be also referred to as “group (II-2)”), and the like.

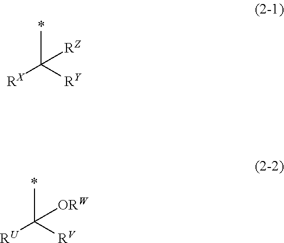

In the above formula (2-1), R^{X} represents a monovalent hydrocarbon group having 1 to 20 carbon atoms; and R^{Y} and R^{Z} each independently represent a monovalent chain hydrocarbon group having 1 to 6 carbon atoms or a monovalent alicyclic hydrocarbon group having 3 to 6 carbon atoms, or R^{Y} and R^{Z} taken together represent a part of a monocyclic alicyclic structure having 3 to 6 ring atoms together with the carbon atom to which R^{Y} and R^{Z} bond.

In the above formula (2-2), R^{U} represents a hydrogen atom or a monovalent hydrocarbon group having 1 to 20 carbon atoms; and R^{V} and R^{W} each independently represent a monovalent chain hydrocarbon group having 1 to 6 carbon atoms or a monovalent alicyclic hydrocarbon group having 3 to 6 carbon atoms, or at least two of R^{U}, R^{V} and R^{W} taken together represent a part of a monocyclic ring structure having 4 to 6 ring atoms together with the carbon atom or C—O to which the at least two of R^{U}, R^{V} and R^{W} bond.

Examples of the monovalent hydrocarbon group having 1 to 20 carbon atoms which may be represented by R^{X} or R^{U} include groups similar to the hydrocarbon groups exemplified as R^{P} in the above formula (3), and the like. Examples of the monovalent chain hydrocarbon group having 1 to 6 carbon atoms which may be represented by R^{Y}, R^{Z}, R^{V} or R^{W} include, among the chain hydrocarbon groups exemplified as R^{P} in the above formula (3), those having 1 to 6 carbon atoms and the like. Examples of the monovalent alicyclic hydrocarbon group having 3 to 6 carbon atoms which may be represented by R^{Y}, R^{Z}, R^{V} or R^{W} include, among the alicyclic hydrocarbon groups exemplified as R^{P} in the above formula (3), those having 3 to 6 carbon atoms and the like.

Examples of the monocyclic alicyclic structure having 3 to 6 ring atoms, a part of which may be represented by R^{Y} and R^{Z} taken together, include:

cycloalkane structures such as a cyclopropane structure, a cyclobutane structure, a cyclopentane structure and a cyclohexane structure;

cycloalkene structures such as a cyclopropene structure, a cyclobutene structure, a cyclopentene structure and a cyclohexene structure; and the like.

Examples of the monocyclic ring structure having 4 to 6 ring atoms, a part of which may be represented by at least two of R^{U}, R^{V} and R^{W} taken together, include, among the structures exemplified as the monocyclic alicyclic structures, a part of which may be represented by R^{Y} and R^{Z}, the monocyclic ring structures having 4 to 6 ring atoms; oxacycloalkane structures such as an oxacyclobutane structure, an oxacyclopentane structure and an oxacyclohexane structure; oxacycloalkene structures such as an oxacyclobutene structure, an oxacyclopentene structure and an oxacyclohexene structure; and the like.

Examples of the structural unit (II) include a structural unit represented by the following formula (2-1A) (hereinafter, may be also referred to as “structural unit (II-1-1)”), a structural unit represented by the following formula (2-1B) (hereinafter, may be also referred to as “structural unit (II-1-2)”), a structural unit represented by the following formula (2-2A) (hereinafter, may be also referred to as “structural unit (II-2-1)”), a structural unit represented by the following formula (2-2B) (hereinafter, may be also referred to as “structural unit (II-2-2)”), and the like.

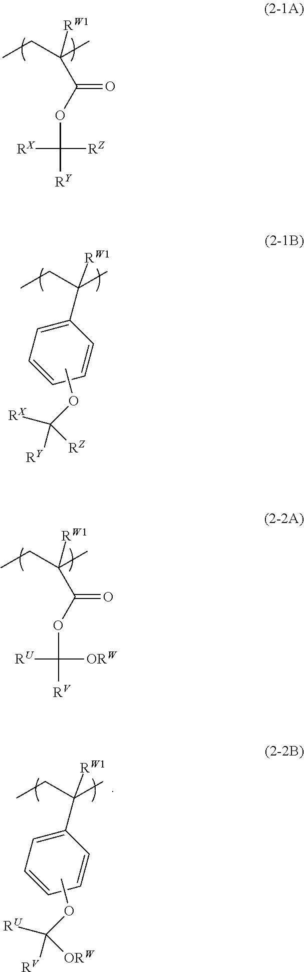

In the above formulae (2-1A), (2-1B), (2-2A) and (2-2B), R^{X}, R^{Y} and R^{Z} are as defined in the above formula (2-1); R^{U}, R^{V} and R^{W} are as defined in the above formula (2-2); and R^{W1}s each independently represent a hydrogen atom, a fluorine atom, a methyl group or trifluoromethyl group.

It is preferred that R^{W1} represents a hydrogen atom or a methyl group, in light of a degree of copolymerization of a monomer that gives a structural unit (II).

The lower limit of the proportion of the structural unit (II) contained with respect to the total structural units constituting the polymer (A1) is preferably 10 mol %, more preferably 25 mol %, still more preferably 40 mol %, and particularly preferably 55 mol %. The upper limit of the proportion of the structural unit (II) is preferably 90 mol %, more preferably 80 mol %, still more preferably 75 mol %, and particularly preferably 70 mol %. When the proportion of the structural unit (II) falls within the above range, the lithography characteristics of the radiation-sensitive resin composition can be further improved.

Structural Unit (IV)

The structural unit (IV) includes a lactone structure, a cyclic carbonate structure, a sultone structure or a combination thereof (except for those corresponding to the structural unit (I) or the structural unit (II)). By virtue of further having the structural unit (IV), the polymer (A1) enables the solubility in a developer solution to be further adjusted, and as a result, the lithography characteristics of the radiation-sensitive resin composition can be further improved. In addition, adhesiveness of the resist pattern to a substrate can be further improved.

Examples of the structural unit (IV) include structural units represented by the following formulae and the like.

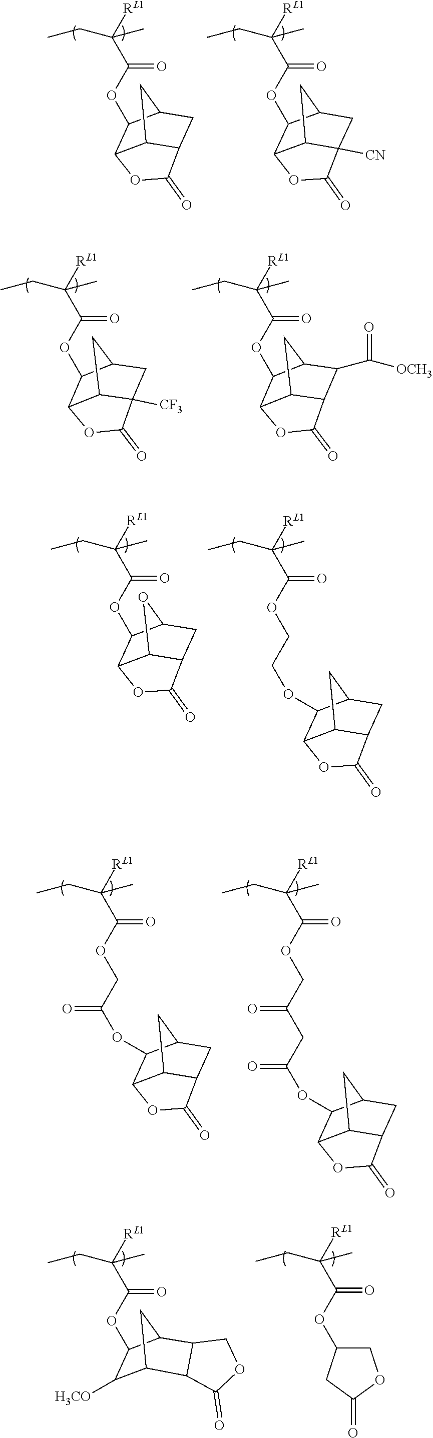

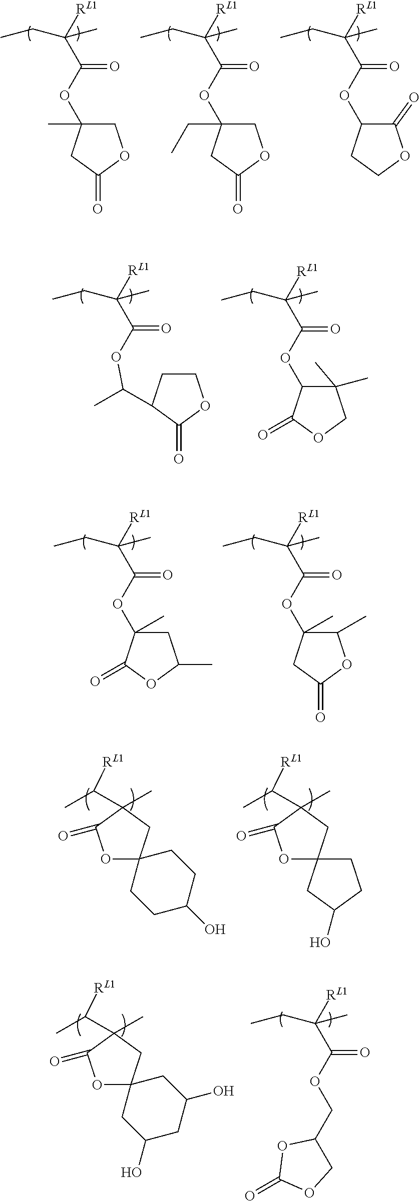

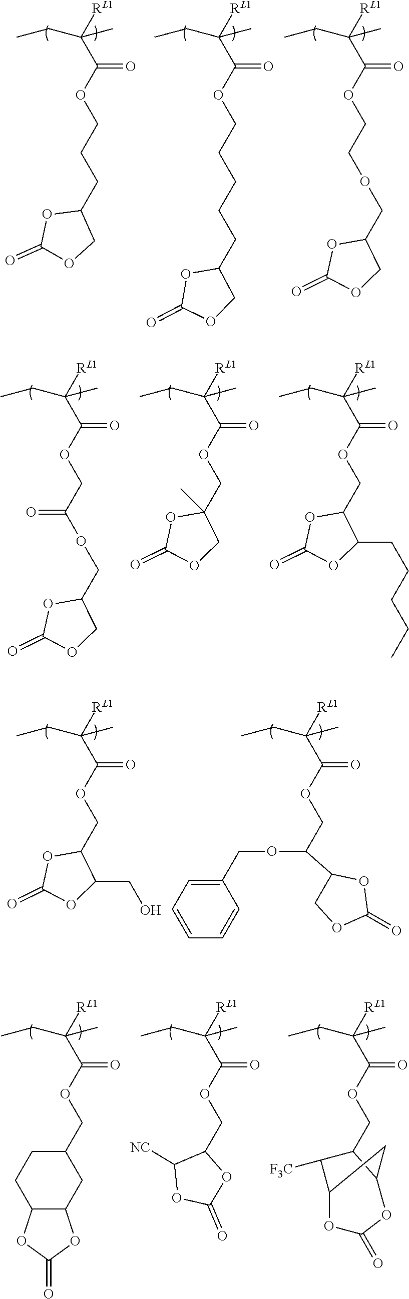

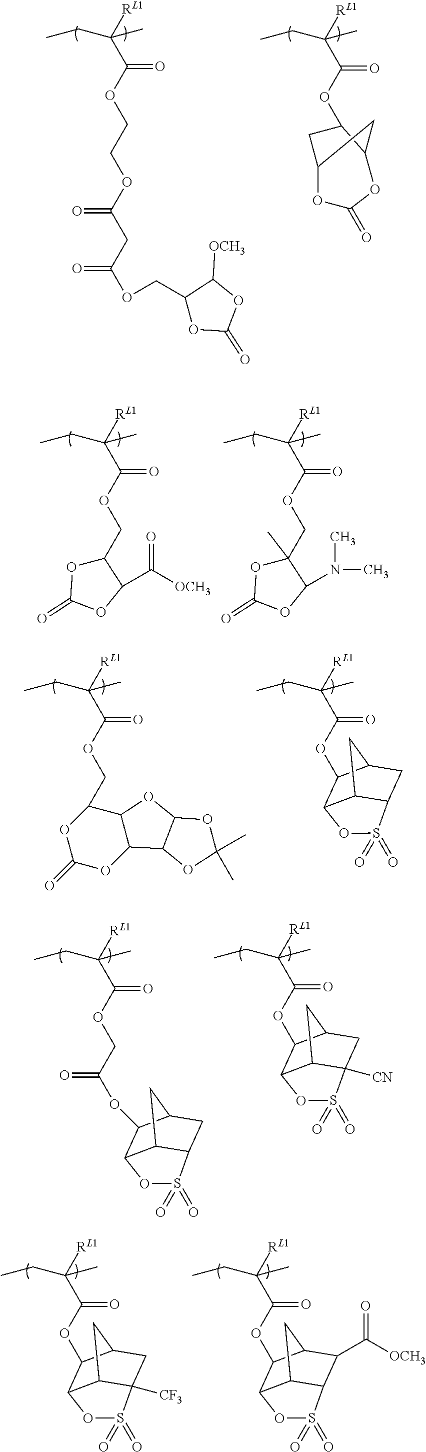

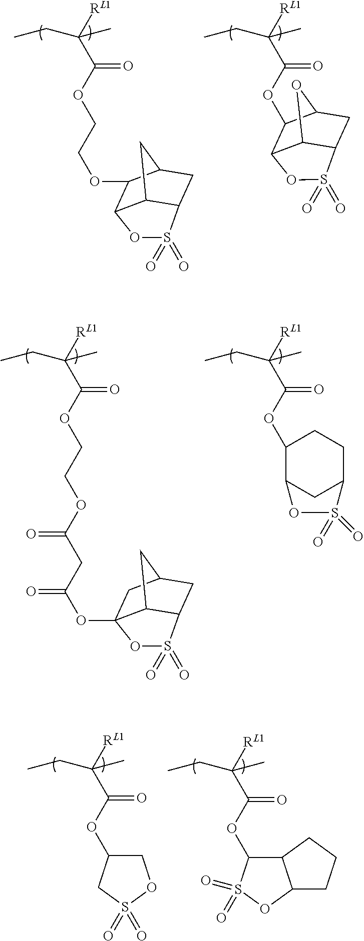

In the above formulae, R^{L1} represents a hydrogen atom, a fluorine atom, a methyl group or a trifluoromethyl group.

The structural unit (IV) is preferably a structural unit that includes a lactone structure, and more preferably a structural unit that includes a norbornanelactone structure or a structural unit that includes a butyrolactone structure.

In a case in which the polymer (A1) has the structural unit (IV), the proportion of the structural unit (IV) is preferably less than 40 mol %, more preferably no greater than 30 mol %, still more preferably no greater than 10 mol %, and particularly preferably 0 mol %. When the proportion of the structural unit (IV) is greater than the upper limit, the lithography characteristics of the radiation-sensitive resin composition may be deteriorated.

Structural Unit (V)

The structural unit (V) includes an alcoholic hydroxy group (except for those corresponding to the structural unit (I) or the structural unit (II)). By virtue of having the structural unit (V), the polymer (A1) enables the solubility in a developer solution to be further adjusted, and as a result, the lithography characteristics of the radiation-sensitive resin composition can be further improved.

Examples of the structural unit (V) include a structural unit derived from 3-hydroxyadamantan-1-yl (meth)acrylate, a structural unit derived from 2-hydroxyethyl (meth)acrylate, and the like.

In a case in which the polymer (A1) has the structural unit (V), the upper limit of the proportion of the structural unit (V) is preferably 30 mol %, and more preferably 15 mol %. The lower limit of the proportion of the structural unit (V) is, for example, 1 mol %.

Other Structural Units

The polymer (A1) may also have other structural unit(s) in addition to the structural units (I), (II), (IV) and (V). The other structural unit is exemplified by a structural unit that includes a polar group, a structural unit that includes a nondissociable hydrocarbon group, and the like (of these, the structural unit that includes an acid-labile group falls under the category of the structural unit (II) herein even if an acid-nonlabile hydrocarbon group is included). Examples of the polar group include a carboxy group, a cyano group, a nitro group, a sulfonamide group, and the like. Examples of a monomer capable of giving the structural unit that includes a nondissociable hydrocarbon group include styrene, vinylnaphthalene, phenyl (meth)acrylate, benzyl (meth)acrylate, n-pentyl (meth)acrylate, cyclohexyl (meth)acrylate, and the like.

In a case in which the polymer (A1) has the other structural unit(s), the upper limit of the proportion of the other structural unit(s) contained with respect to the total structural units constituting the polymer (A1) is preferably 30 mol %, and more preferably 15 mol %. The lower limit of the proportion of the other structural unit(s) is, for example, 1 mol %.

The lower limit of the polystyrene-equivalent weight average molecular weight (Mw) as determined by gel permeation chromatography (GPC) of the polymer (A1) is preferably 2,000, more preferably 3,000, still more preferably 4,000, and particularly preferably 5,000. The upper limit of the Mw is preferably 50,000, more preferably 30,000, still more preferably 20,000, and particularly preferably 10,000. When the Mw of the polymer (A1) falls within the above range, the coating characteristics of the radiation-sensitive resin composition can be further improved.

The upper limit of a ratio (Mw/Mn) of Mw to a polystyrene-equivalent number average molecular weight (Mn) as determined by GPC of the polymer (A1) is preferably 5, more preferably 3, and still more preferably 2. The lower limit of the ratio is typically 1, and preferably 1.1.

The Mw and the Mn of the polymer herein are determined by using gel permeation chromatography (GPC) under the following conditions.

GPC columns: “G2000 HXL”×2, “G3000 HXL”×1, and “G4000 HXL”×1, available from Tosoh Corporation;

column temperature: 40° C.;

elution solvent: tetrahydrofuran (Wako Pure Chemical Industries, Ltd.);

flow rate: 1.0 mL/min;

sample concentration: 1.0% by mass;

s amount of injected sample: 100 μL;

detector: differential refractometer; and

standard substance: mono-dispersed polystyrene

The lower limit of the content of the polymer (A1) with respect to the total solid content of the radiation-sensitive resin composition is preferably 50% by mass, more preferably 60% by mass, and still more preferably 70% by mass. The “total solid content” of the radiation-sensitive resin composition as referred to herein means total components other than the solvent (C).

Synthesis Procedure of Polymer (A1)

The polymer (A1) can be synthesized by, for example, polymerizing the monomer that gives each structural unit according to a well-known procedure. In a case in which the structural unit (I) is a structural unit derived from hydroxystyrene, vinylnaphthalene or the like, such a structural unit may be formed by, for example, using acetoxystyrene, acetoxyvinylnaphthalene or the like as the monomer to obtain a polymer, and hydrolysizing the polymer in the presence of a base.

### (A2) Polymer

The polymer (A2) has at least one of a fluorine atom and a silicon atom, and also has the structural unit (III). The fluorine atom and the silicon atom may bond to any of the main chain, the side chain and the terminal of the polymer (A2), and preferably bond to the side chain. The polymer (A2) typically has a fluorine atom and a silicon atom in a structural unit that includes a fluorine atom and/or a silicon atom, or in the structural unit (III).

It is preferred that in the polymer (A2), a total percentage content of the fluorine atom and silicon atom is greater than that of the polymer (A1). When the total percentage content of the fluorine atom and silicon atom in the polymer (A2) is greater than that of the polymer (A1), the polymer (A2) tends to be further localized to a surface layer of the resist film due to characteristic features resulting from the hydrophobicity thereof.

The lower limit of the total percentage content of the fluorine atom and silicon atom of the polymer (A2) is preferably 1 atom %, and more preferably 3 atom %. The upper limit of the total percentage content of the fluorine atom and silicon atom is preferably 30 atom %, and more preferably 20 atom %. The total percentage content of the fluorine atom and silicon atom may be calculated by: identification of the polymer structure through determination on a ¹³C-NMR spectrum of the polymer (A2); and calculation from the structure.

The polymer (A2) may have, in addition to the structural unit (III), a structural unit that includes a group represented by the formula (A) described later (hereinafter, may be also referred to as “structural unit (VI)”). Furthermore, polymer (A2) may also have the structural units (I), (II), (IV), (V) and the like in the polymer (A1), as well as structural unit(s) other than these structural units (other structural units). The polymer (A2) may have one, or two or more types of each structural unit. Each structural unit is as described below.

Structural Unit (III)

The structural unit (III) includes the alkali-labile group (b).

The structural unit (III) is exemplified by a structural unit that includes a group represented by the following formula (1) (hereinafter, may be also referred to as “group (III)”), and the like.

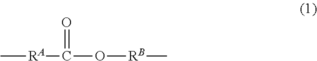

In the above formula (1), R^{A} represents a single bond, a methanediyl group or a fluorinated methanediyl group; and R^{B} represents a single bond, a methanediyl group, a fluorinated methanediyl group, an ethanediyl group or fluorinated ethanediyl group, or R^{A} and R^{B} taken together represent a part of an aliphatic heterocyclic structure having 4 to 20 ring atoms together with —COO— to which R^{A} and R^{B} bond, wherein at least one of R^{A} and R^{B} includes a fluorine atom.

Examples of the fluorinated methanediyl group which may be represented by R^{A} or R^{B} include a fluoromethanediyl group, a difluoromethanediyl group, and the like.

Examples of the fluorinated ethanediyl group which may be represented by R^{B} include a fluoroethanediyl group, a difluoroethanediyl group, a trifluoroethanediyl group, a tetrafluoroethanediyl group, and the like.

R^{A} represents preferably a single bond, a methanediyl group or a difluoromethanediyl group.

R^{B} represents preferably a single bond, a methanediyl group, an ethanediyl group, a difluoromethanediyl group or a trifluoroethanediyl group.

Examples of the aliphatic heterocyclic structure having 4 to 20 ring atoms represented by R^{A} and R^{B} taken together include lactone structures such as a butyrolactone structure and a valerolactone structure, and the like.

Examples of the structural unit (III) include a structural unit represented by the following formula (1A) (hereinafter, may be also referred to as “structural unit (III-1)”), a structural unit represented by the following formula (1B) (hereinafter, may be also referred to as “structural unit (III-2)”), and the like.

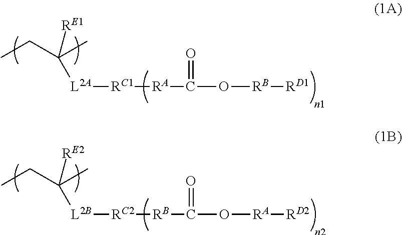

In the above formulae (1A) and (1B), R^{A} and R^{B} are as defined in the above formula (1).

In the above formula (1A), R^{E1} represents a hydrogen atom, a fluorine atom, a methyl group or a trifluoromethyl group; L^{2A} represents a single bond, an oxygen atom or a divalent organic group having 1 to 20 carbon atoms; R^{C1} represents an organic group having 1 to 20 carbon atoms with a valency of (n1+1); R^{D1} represents a hydrogen atom, a fluorine atom or a monovalent organic group having 1 to 20 carbon atoms that includes a fluorine atom; and n1 is an integer of 1 to 3, wherein in a case in which n1 is no less than 2, a plurality of R^{A}s are identical or different, a plurality of R^{B}s are identical or different, and a plurality of R^{D1}s are identical or different.

In the above formula (1B), R^{E2} represents a hydrogen atom, a fluorine atom, a methyl group or a trifluoromethyl group; L^{2B} represents a single bond, an oxygen atom or a divalent organic group having 1 to 20 carbon atoms; R^{C2} represents an organic group having 1 to 20 carbon atoms with a valency of (n2+1); R^{D2} represents a hydrogen atom, a fluorine atom or a monovalent organic group having 1 to 20 carbon atoms that includes a fluorine atom; and n2 is an integer of 1 to 3, wherein in a case in which n2 is no less than 2, a plurality of R^{A}s are identical or different, a plurality of R^{B}s are identical or different, and a plurality of R^{D2}s are identical or different.

R^{E1} and R^{E2} represent, in light of a degree of copolymerization of a monomer that gives the structural unit (III), preferably a hydrogen atom or a methyl group, and more preferably a methyl group.

Examples of the divalent organic group having 1 to 20 carbon atoms which may be represented by L^{2A} or L^{2B} include groups obtained by removing one hydrogen atom from the monovalent organic groups exemplified as R^{P} in the above formula (3), and the like.

As L^{2A} and L²B, —COO— or a benzenediyl group is preferred.

Examples of the organic group having 1 to 20 carbon atoms with a valency of (n1+1) represented by R^{C1} and the organic group having 1 to 20 carbon atoms with a valency of (n2+1) represented by R^{C2} include groups obtained by removing n1 hydrogen atoms and n2 hydrogen atoms, respectively, from the monovalent organic groups exemplified as R^{P} in the above formula (3), and the like.

R^{D1} represents preferably a fluorine atom or a trifluoromethyl group. R^{D2} represents preferably a hydrogen atom or a fluorine atom.

Examples of the monovalent organic group having 1 to 20 carbon atoms that includes a fluorine atom which may be represented by R^{D1} or R^{D2} include, among the monovalent organic groups exemplified as R^{P} in the above formula, those that include a fluorine atom, and the like.

The proportion of the structural unit (III) contained with respect to the total structural units constituting the polymer (A2) is preferably greater than 30 mol %, more preferably greater than 55 mol %, still more preferably no less than 70 mol %, and particularly preferably no less than 95 mol %. When the proportion of the structural unit (III) falls within the above range, the lithography characteristics of the radiation-sensitive resin composition can be further improved.

Structural Unit (VI)

The structural unit (VI) includes a group represented by the following formula (A) (hereinafter, may be also referred to as “group (VI)”) (except for those corresponding to the structural unit (III)).

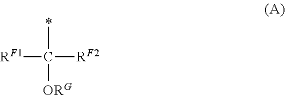

In the above formula (A), R^{F1} and R^{F2} each independently represent a fluorinated alkyl group having 1 to 10 carbon atoms; and R^{G} represents a hydrogen atom or a monovalent organic group having 1 to 20 carbon atoms.

Examples of the fluorinated alkyl group having 1 to 10 carbon atoms represented by R^{F1} or R^{F2} include a fluoromethyl group, a difluoromethyl group, a trifluoromethyl group, a trifluoroethyl group, a pentafluoroethyl group, a heptafluoropropyl group, a nonafluorobutyl group, and the like. Of these, a perfluoroalkyl group is preferred, and a trifluoromethyl group is more preferred.

Examples of the monovalent organic group having 1 to 20 carbon atoms which may be represented by R^{G} include groups similar to the organic groups exemplified as R^{P} in the above formula (3), and the like.

R^{G} represents preferably a hydrogen atom.

Examples of the monomer that gives the structural unit (VI) include hydroxydi(trifluoromethyl)methylcyclohexyl (meth)acrylate, hydroxydi(trifluoromethyl)pentyl (meth)acrylate, and the like.

In the case in which the polymer (A2) has the structural unit (VI), the lower limit of the proportion of the structural unit (VI) contained with respect to the total structural units constituting the polymer (A2) is preferably 1 mol %, and more preferably 3 mol %. The upper limit of the structural unit is preferably 30 mol %, and more preferably 10 mol %. When the proportion of the structural unit (VI) falls within the above range, the lithography characteristics of the radiation-sensitive resin composition can be further improved.

In the case in which the polymer (A2) has the structural unit (I) in the polymer (A1), the lower limit of the proportion of the structural unit (I) contained with respect to the total structural units constituting the polymer (A2) is preferably 1 mol %, and more preferably 5 mol %. The upper limit of the proportion of the structural unit (I) is preferably 30 mol %, and more preferably 15 mol %.

In the case in which the polymer (A2) has the structural unit (II) in the polymer (A1), the lower limit of the proportion of the structural unit (II) contained with respect to the total structural units constituting the polymer (A2) is preferably 10 mol %, more preferably 25 mol %, and still more preferably 40 mol %. The upper limit of the proportion of the structural unit (II) is preferably 60 mol %, and more preferably 50 mol %.

Other Structural Units

The polymer (A2) may have other structural unit(s) in addition to the structural units (I) to (VI). The other structural unit is exemplified by a structural unit derived from fluorinated alkyl (meth)acrylate, and the like. Examples of the fluorinated alkyl (meth)acrylate that gives such a structural unit include trifluoroethyl (meth)acrylate, pentafluoro-n-propyl (meth)acrylate, hexafluoro-i-propyl (meth)acrylate, and the like. The upper limit of the proportion of the other structural unit is preferably 30 mol %, and more preferably 10 mol %. The lower limit of the proportion of the other structural unit is, for example, 1 mol %.

The lower limit of the Mw of the polymer (A2) is preferably 2,000, more preferably 4,000, still more preferably 6,000, and particularly preferably 8,000. The upper limit of the Mw is preferably 50,000, more preferably 30,000, still more preferably 20,000 and particularly preferably 15,000. When the Mw of the polymer (A2) falls within the above range, the coating characteristics of the radiation-sensitive resin composition can be further improved.

The upper limit of a ratio (Mw/Mn) of the Mw to a polystyrene-equivalent number average molecular weight (Mn) as determined by GPC of the polymer (A2) is preferably 5, more preferably 3, and still more preferably 2. The lower limit of the ratio is typically 1, and preferably 1.1.

The lower limit of the content of the polymer (A2) with respect to 100 parts by mass of the polymer (A1) is preferably 0.1 parts by mass, more preferably 1 part by mass, still more preferably 2 parts by mass, and particularly preferably 4 parts by mass. The upper limit of the content of the polymer (A2) is preferably 20 parts by mass, more preferably 15 parts by mass, and still more preferably 10 parts by mass.

Synthesis Procedure of Polymer (A2)

The polymer (A2) can be synthesized by, for example, polymerizing the monomer that gives each structural unit according to a well-known procedure, similarly to the polymer (A1).

(B1) Compound

The compound (B1) generates upon an irradiation with a radioactive ray an acid (hereinafter, may be also referred to as “acid (I)”) capable of dissociating the acid-labile group (a) under a condition involving a temperature T^{X}° C. of no less than 80° C. and no greater than 130° C. for 1 min. Heating at a temperature of T^{X}° C. falling within the range of 80° C. to 130° C. and a temperature exceeding T^{X}° C. for a time period of 1 min or less than 1 min in, e.g., post exposure baking (PEB) or the like, allows the acid-labile group (a) to be dissociated by virtue of the action of the acid (I) generated from the compound (B1) upon an irradiation with a radioactive ray.

The lower limit of the temperature T^{X} is typically 80° C., preferably 85° C., more preferably 95° C., and still more preferably 105° C. The upper limit of the temperature T^{X} is typically 130° C., preferably 125° C., more preferably 120° C., and still more preferably 115° C.

The acid (I) is exemplified by a sulfonic acid (hereinafter, may be also referred to as “acid (I-1)”), a disulfonylimidic acid (hereinafter, may be also referred to as “acid (I-2)”), a sulfomalonic acid ester (hereinafter, may be also referred to as “acid (I-3)”), a carboxylic acid in which a fluorine atom bonds to a carbon atom adjacent to the carboxy group (hereinafter, may be also referred to as “acid (I-4)”), and the like.

Examples of the acid (I-1) include perfluoroalkanesulfonic acid, alkanesulfonic acid, a compound represented by the following formula (4-1) (hereinafter, may be also referred to as “compound (4-1)”), and the like.

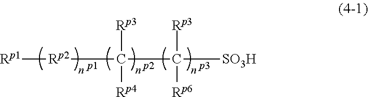

In the above formula (4-1), R^{p1} represents a monovalent group that includes a ring structure having 5 or more ring atoms; R^{p2} represents a divalent linking group; R^{p3} and R^{p4} each independently represent a hydrogen atom, a fluorine atom, a monovalent hydrocarbon group having 1 to 20 carbon atoms or a monovalent fluorinated hydrocarbon group having 1 to 20 carbon atoms; R^{p5} and R^{p6} each independently represent a fluorine atom or a monovalent fluorinated hydrocarbon group having 1 to 20 carbon atoms; n^{p1} is an integer of 0 to 10; n^{p2} is an integer of 0 to 10; and n^{p3} is an integer of 1 to 10, wherein the sum of n^{p1}, n^{p2} and n^{p3} is 0 to 30, and wherein in a case in which n^{p1} is no less than 2, a plurality of R^{p2}s are each identical or different, in a case in which n^{p2} is no less than 2, a plurality of R^{p3}s are each identical or different and a plurality of R^{p4}s are each identical or different, and in a case in which n^{p3} is no less than 2, a plurality of R^{p5}s are each identical or different and a plurality of R^{p6}s are each identical or different.

The monovalent group that includes a ring structure having 5 or more ring atoms which is represented by R^{p1} is exemplified by: a monovalent group that includes an alicyclic structure having 5 or more ring atoms; a monovalent group that includes an aliphatic heterocyclic structure having 5 or more ring atoms; a monovalent group that includes an aromatic ring structure having 5 or more ring atoms; a monovalent group that includes an aromatic heterocyclic structure having 5 or more ring atoms; and the like.

Examples of the alicyclic structure having 5 or more ring atoms include:

monocyclic saturated alicyclic structures such as a cyclopentane structure, a cyclohexane structure, a cycloheptane structure, a cyclooctane structure, a cyclononane structure, a cyclodecane structure and a cyclododecane structure;

monocyclic unsaturated alicyclic structures such as a cyclopentene structure, a cyclohexene structure, a cycloheptene structure, a cyclooctene structure and a cyclodecene structure;

polycyclic saturated alicyclic structures such as a norbornane structure, an adamantane structure, a tricyclodecane structure and a tetracyclododecene structure;

polycyclic unsaturated alicyclic structures such as a norbornene structure and a tricyclodecene structure; and the like.

Examples of the aliphatic heterocyclic structure having 5 or more ring, atoms include:

lactone structures such as a hexanolactone structure and a norbornanelactone structure;

sultone structures such as a hexanosultone structure and a norbornanesultone structure;

oxygen atom-containing heterocyclic structures such as an oxacycloheptane structure and an oxanorbornane structure;

nitrogen atom-containing heterocyclic structures such as an azacyclohexane structure and a diazabicyclooctane structure;

sulfur atom-containing heterocyclic structures such as a thiacyclohexane structure and a thianorbornane structure; and the like.

Examples of the aromatic ring structure having 5 or more ring atoms include a benzene structure, a naphthalene structure, a phenanthrene structure, an anthracene structure, and the like.

Examples of the aromatic heterocyclic structure having 5 or more ring atoms include:

oxygen atom-containing heterocyclic structures such as a furan structure, a pyran structure, a benzofuran structure and a benzopyran structure;

nitrogen atom-containing heterocyclic structures such as a pyridine structure, a pyrimidine structure and an indole structure; and the like.

The lower limit of the number of ring atoms of the ring structure included in R^{p1} is preferably 6, more preferably 8, still more preferably 9, and particularly preferably 10. The upper limit of the number of ring atoms is preferably 15, more preferably 14, still more preferably 13, and particularly preferably 12. When the number of ring atoms falls within the above range, the aforementioned diffusion length of the acid may be further properly reduced, and as a result, the lithography characteristics of the radiation-sensitive resin composition can be further improved.

A part or all of hydrogen atoms included in the ring structure of R^{p1} may be substituted with a substituent. Examples of the substituent include halogen atoms such as a fluorine atom, a chlorine atom, a bromine atom and an iodine atom, a hydroxy group, a carboxy group, a cyano group, a nitro group, an alkoxy group, an alkoxycarbonyl group, an alkoxycarbonyloxy group, an acyl group, an acyloxy group, and the like. Of these, the hydroxy group is preferred.

R^{p1} represents preferably a monovalent group that includes an alicyclic structure having 5 or more ring atoms or a monovalent group that includes an aliphatic heterocyclic structure having 5 or more ring atoms, more preferably a monovalent group that includes an alicyclic structure having 9 or more ring atoms or a monovalent group that includes an aliphatic heterocyclic structure having 9 or more ring atoms, still more preferably an adamantyl group, a hydroxyadamantyl group, a norbornanelactone-yl group, a norbornanesultone-yl group or a 5-oxo-4-oxatricyclo[4.3.1.1^{3,8}]undecan-yl group, and particularly preferably an adamantyl group.

Examples of the divalent linking group represented by R^{p2} include a carbonyl group, an ether group, a carbonyloxy group, a sulfide group, a thiocarbonyl group, a sulfonyl group, a divalent hydrocarbon group, and the like. Of these, the carbonyloxy group, the sulfonyl group, an alkanediyl group or a divalent alicyclic saturated hydrocarbon group is preferred, the carbonyloxy group or the divalent alicyclic saturated hydrocarbon group is more preferred, the carbonyloxy group or a norbornanediyl group is still more preferred, and the carbonyloxy group is particularly preferred.

The monovalent hydrocarbon group having 1 to 20 carbon atoms which may be represented by R^{p3} or R^{p4} is exemplified by an alkyl group having 1 to 20 carbon atoms, and the like. The monovalent fluorinated hydrocarbon group having 1 to 20 carbon atoms which may be represented by R^{p3} or R^{p4} is exemplified by a fluorinated alkyl group having 1 to 20 carbon atoms, and the like. R^{p3} and R^{p4} each independently represent preferably a hydrogen atom, a fluorine atom or a fluorinated alkyl group, more preferably a fluorine atom or a perfluoroalkyl group, and still more preferably a fluorine atom or a trifluoromethyl group.

The monovalent fluorinated hydrocarbon group having 1 to 20 carbon atoms which may be represented by R^{p5} or R^{p6} is exemplified by a fluorinated alkyl group having 1 to 20 carbon atoms, and the like. R^{p5} and R^{p6} each independently represent preferably a fluorine atom or a fluorinated alkyl group, more preferably a fluorine atom or a perfluoroalkyl group, still more preferably a fluorine atom or a trifluoromethyl group, and particularly preferably a fluorine atom.

In the above formula (4-1), n^{p1} is preferably an integer of 0 to 5, more preferably an integer of 0 to 3, still more preferably an integer of 0 to 2, and particularly preferably 0 or 1.

In the above formula (4-1), n^{p2} is preferably an integer of 0 to 5, more preferably an integer of 0 to 2, still more preferably 0 or 1, and particularly preferably 0.

The lower limit of n^{p3} is preferably 1, and more preferably 2. When n^{p3} is no less than 1, the strength of the acid generated from the compound (4-1) may be increased, and consequently the lithography characteristics of the radiation-sensitive resin composition can be further improved. The upper limit of n^{p3} is preferably 4, more preferably 3, and still more preferably 2.

The lower limit of the sum of n^{P}, n^{p2} and n^{p3}, i.e., (n^{p1}+n^{p2}+n^{p3}), is preferably 1, and more preferably 4. The upper limit of the sum of n^{p1}, n^{p2} and n^{p3} is preferably 20, and more preferably 10.

Examples of the acid (I-2) include a compound represented by the following formula (4-2), and the like.

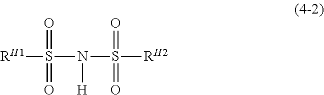

In the above formula (4-2), R^{H1} and R^{H2} each independently represent a monovalent organic group having 1 to 20 carbon atoms, or R^{H1} and R^{H2} taken together represent a part of a ring structure having 6 to 12 ring atoms together with the sulfur atom and the nitrogen atom in the formula (4-2).

Examples of the acid (I-3) include a compound represented by the following formula (4-3), and the like.

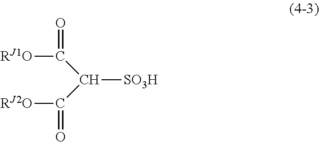

In the above formula (4-3), R^{J1} and R^{J2} each independently represent a monovalent organic group having 1 to 20 carbon atoms, or R^{J1} and R^{J2} taken together represent a part of a ring structure having 7 to 12 ring atoms together with —O—CO—CH—CO—O— in the formula (4-3).

Examples of the acid (I-4) include a compound represented by the following formula (4-4), and the like.

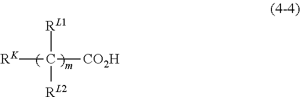

In the above formula (4-4), R^{K} represents a hydrogen atom, a fluorine atom or a monovalent organic group having 1 to 30 carbon atoms; m is an integer of 1 to 3, wherein: in a case in which m is 1, R^{L1} and R^{L2} each independently represent a fluorine atom or a monovalent fluorinated hydrocarbon group having 1 to 20 carbon atoms, or R^{L1} and R^{L2} taken together represent a part of a ring structure having 3 to 20 ring atoms together with the carbon atom to which R^{L1} and R^{L2} bond; and in a case in which m is no less than 2, a plurality of R^{L1}s are identical or different and each represent a fluorine atom or a monovalent fluorinated hydrocarbon group having 1 to 20 carbon atoms, a plurality of R^{L2}s are identical or different and each represent a fluorine atom or a monovalent fluorinated hydrocarbon group having 1 to 20 carbon atoms, or at least two of a plurality of R^{L1}s and a plurality of R^{L2}s taken together represent a part of a ring structure having 4 to 20 ring atoms together with the carbon chain to which the at least two of the plurality of R^{L1}s and R^{L2}s bond.

The compound (B1) is typically a salt of a radiation-sensitive cation with an anion (hereinafter, may be also referred to as “anion (I)”) obtained by removing a proton from the acid group of the acid (I). In a light-exposed region, the compound (B1) gives the acid (I) from the anion (I) and a proton generated by decomposition of the radiation-sensitive cation through an action of a radioactive ray. This acid (I) is capable of dissociating the acid-labile group (a) of the polymer (A1) under a condition of 80° C. for 1 min. In other words, the compound (B1) serves as an acid generating agent that leads to a change in solubility into a developer solution by permitting dissociation of the acid-labile group of the polymer (A1) in the light-exposed region.

Examples of the anion (I) include: a sulfonate anion that gives the acid (I-1); a disulfonylimide anion that gives the acid (I-2); an anion having a sulfonate group that bonds to a methylene carbon atom of a malonic acid ester group that gives the acid (I-3); an anion in which a fluorine atom bonds to a carbon atom adjacent to a carboxylate group that gives the acid (I-4); and the like.

The radiation-sensitive cation is a cation decomposed upon irradiation with exposure light and/or an electron beam. Taking a compound consisting of the sulfonate anion and the radiation-sensitive onium cation as an example, sulfonic acid is produced in a light-exposed region from the sulfonate anion and the proton produced by decomposition of the radiation-sensitive onium cation.

Examples of the radiation-sensitive cation include: a cation represented by the following formula (r-a) (hereinafter, may be also referred to as “cation (r-a)”); a cation represented by the following formula (r-b) (hereinafter, may be also referred to as “cation (r-b)”); a cation represented by the following formula (r-c) (hereinafter, may be also referred to as “cation (r-c)”); and the like.

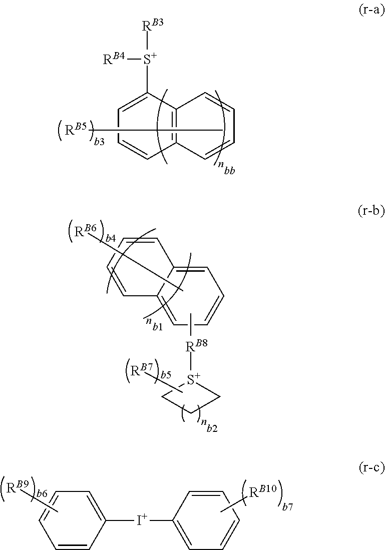

In the above formula (r-a), R^{B3} and R^{B4} each independently represent a monovalent organic group having 1 to 20 carbon atoms; b3 is an integer of 0 to 11, wherein in a case in which b3 is 1, R^{B5} represents a monovalent organic group having 1 to 20 carbon atoms, a hydroxy group, a nitro group or a halogen atom, and in a case in which b3 is no less than 2, a plurality of R^{B5}s are each identical or different, and represent a monovalent organic group having 1 to 20 carbon atoms, a hydroxy group, a nitro group or a halogen atom, or the plurality of R^{B5}s taken together represent a part of a ring structure having 4 to 20 ring atoms together with the carbon chain to which the plurality of R^{B5}s bond; and n_{bb} is an integer of 0 to 3.

Examples of the monovalent organic group having 1 to 20 carbon atoms represented by R^{B3}, R^{B4} or R^{B5} include groups similar to the organic groups exemplified as R^{P} in the above formula (3), and the like.

R^{B3} and R^{B4} each represent preferably a monovalent unsubstituted hydrocarbon group having 1 to 20 carbon atoms or a hydrocarbon group obtained therefrom by substituting a hydrogen atom included therein with a substituent, more preferably a monovalent unsubstituted aromatic hydrocarbon group having 6 to 18 carbon atoms or an aromatic hydrocarbon group obtained therefrom by substituting a hydrogen atom included therein with a substituent, and still more preferably a substituted or unsubstituted phenyl group.

The substituent which may substitute for the hydrogen atom included in the monovalent hydrocarbon group having 1 to 20 carbon atoms which may be represented by R^{B3} or R^{B4} is preferably a substituted or unsubstituted monovalent hydrocarbon group having 1 to 20 carbon atoms, —OSO₂—R^{k}, —SO₂—R^{k}, —OR^{k}, —COOR^{k}, —O—CO—R^{k}, —O—R^{kk}—COOR^{k}, —R^{kk}—CO—R^{k} or —S—R^{k}, wherein R^{k} represents a monovalent hydrocarbon group having 1 to 10 carbon atoms; and R^{kk} represents a single bond or a divalent hydrocarbon group having 1 to 10 carbon atoms.

R^{B5} represents preferably a substituted or unsubstituted monovalent hydrocarbon group having 1 to 20 carbon atoms, —OSO₂—R^{k}, —SO₂—R^{k}, —OR^{k}, —COOR^{k}, —O—CO—R^{k}, —O—R^{kk}—COOR^{k}, —R^{kk}—CO—R^{k} or —S—R^{k}, wherein R^{k} represents a monovalent hydrocarbon group having 1 to 10 carbon atoms; and R^{kk} represents a single bond or a divalent hydrocarbon group having 1 to 10 carbon atoms.

In the above formula (r-b), b4 is an integer of 0 to 9; wherein in a case in which b4 is 1, R^{B6} represents a monovalent organic group having 1 to 20 carbon atoms, a hydroxy group, a nitro group or a halogen atom, and in a case in which b4 is no less than 2, a plurality of R^{B6}s are each identical or different and represent a monovalent organic group having 1 to 20 carbon atoms, a hydroxy group, a nitro group or a halogen atom, or the plurality of R^{B6}s taken together represent a part of a ring structure having 4 to 20 ring atoms together with the carbon chain to which the plurality of R^{B6}s bond; b5 is an integer of 0 to 10, wherein in a case in which b5 is 1, R^{B7} represents a monovalent organic group having 1 to 20 carbon atoms, a hydroxy group, a nitro group or a halogen atom, and in a case in which b5 is no less than 2, a plurality of R^{B7}s are each identical or different and represent a monovalent organic group having 1 to 20 carbon atoms, a hydroxy group, a nitro group or a halogen atom, or the plurality of R^{B7}s taken together represent a part of a ring structure having 3 to 20 ring atoms taken together with the carbon atom or carbon chain to which the plurality of R^{B7}s bond; n_{b2} is an integer of 0 to 3; R^{B8} represents a single bond or a divalent organic group having 1 to 20 carbon atoms; and n_{b1} is an integer of 0 to 2.

R^{B6} and R^{B7} each represent preferably a substituted or unsubstituted monovalent hydrocarbon group having 1 to 20 carbon atoms, —OR^{k}, —COOR^{k}, —O—CO—R^{k}, —O—R^{kk}—COOR^{k} or —R^{kk}—CO—R^{k}, wherein R^{k} represents a monovalent hydrocarbon group having 1 to 10 carbon atoms; and R^{kk} represents a single bond or a divalent hydrocarbon group having 1 to 10 carbon atoms.

Examples of R^{B8} include groups obtained by removing one hydrogen atom from the monovalent organic groups having 1 to 20 carbon atoms exemplified as R^{P} in the above formula (3), and the like.

In the above formula (r-c), b6 is an integer of 0 to 5, wherein in a case in which b6 is 1, R^{B9} represents a monovalent organic group having 1 to 20 carbon atoms, a hydroxy group, a nitro group or a halogen atom, in a case in which b6 is no less than 2, a plurality of R^{B9}s are each identical or different and represent a monovalent organic group having 1 to 20 carbon atoms, a hydroxy group, a nitro group or a halogen atom, or the plurality of R^{B9}s taken together represent a part of a ring structure having 4 to 20 ring atoms together with the carbon chain to which the plurality of R^{B9}s bond; and b7 is an integer of 0 to 5, wherein in a case in which b7 is 1, R^{B10} represents a monovalent organic group having 1 to 20 carbon atoms, a hydroxy group, a nitro group or a halogen atom, and in a case in which b7 is no less than 2, a plurality of R^{B10}s are each identical or different and represent a monovalent organic group having 1 to 20 carbon atoms, a hydroxy group, a nitro group or a halogen atom, or the plurality of R^{B10}s taken together represent a part of a ring structure having 4 to 20 ring atoms together with the carbon chain to which the plurality of R^{B10}s bond.

R^{B9} and R^{B10} each represent preferably a substituted or unsubstituted monovalent hydrocarbon group having 1 to 20 carbon atoms, —OSO₂—R^{k}, —SO₂—R^{k}, —OR^{k}, —COOR^{k}, —O—CO—R^{k}, —O—R^{kk}—COOR^{k}, —R^{kk}—CO—R^{k}, —S—R^{k}, or a ring structure taken together represented by at least two of R^{B9} and R^{B10}, wherein R^{k} represents a monovalent hydrocarbon group having 1 to 10 carbon atoms; and R^{kk} represents a single bond or a divalent hydrocarbon group having 1 to 10 carbon atoms.

Examples of the monovalent hydrocarbon group having 1 to 20 carbon atoms which may be represented by R^{B5}, R^{B6}, R^{B7}, R^{B9} or R^{B10} include groups similar to those exemplified as the hydrocarbon groups which may be represented by R^{P} in the above formula (3), and the like.

Examples of the divalent organic group which may be represented by R^{B8} include groups obtained by removing one hydrogen atom from the monovalent organic group having 1 to 20 carbon atoms exemplified as R^{P} in the above formula (3), and the like.

Examples of the substituent which may substitute for the hydrogen atom included in the hydrocarbon group which may be represented by R^{B5}, R^{B6}, R^{B7}, R^{B9} or R^{B10} include halogen atoms such as a fluorine atom, a chlorine atom, a bromine atom and an iodine atom, a hydroxy group, a carboxy group, a cyano group, a nitro group, an alkoxy group, an alkoxycarbonyl group, an alkoxycarbonyloxy group, an acyl group, an acyloxy group, and the like. Of these, the halogen atom is preferred, and a fluorine atom is more preferred.

R^{B5}, R^{B6}, R^{B7}, R^{B9} and R^{B10} each represent preferably an unsubstituted linear or branched monovalent alkyl group, a monovalent fluorinated alkyl group, an unsubstituted monovalent aromatic hydrocarbon group, —OSO₂—R^{k} or —SO₂—R^{k}, more preferably a fluorinated alkyl group or an unsubstituted monovalent aromatic hydrocarbon group, and still more preferably a fluorinated alkyl group.

In the formula (r-a), b3 is preferably an integer of 0 to 2, more preferably 0 or 1, and still more preferably 0; and n_{bb} is preferably 0 or 1, and still more preferably 0. In the formula (r-b), b4 is preferably an integer of 0 to 2, more preferably 0 or 1, and still more preferably 0; b5 is preferably an integer of 0 to 2, more preferably 0 or 1, and still more preferably 0; n_{b2} is preferably 2 or 3, and more preferably 2; and n_{b1} is preferably 0 or 1, and more preferably 0. In the formula (r-c), b6 or b7 is preferably an integer of 0 to 2, more preferably 0 or 1, and still more preferably 0.

Of these, the cation (r-a) or the cation (r-b) is preferred as the radiation-sensitive cation.

s Examples of the compound (B1) include compounds represented by the following formulae (i-1) to (i-14) (hereinafter, may be also referred to as “compounds (i-1) to (i-14)”), and the like.

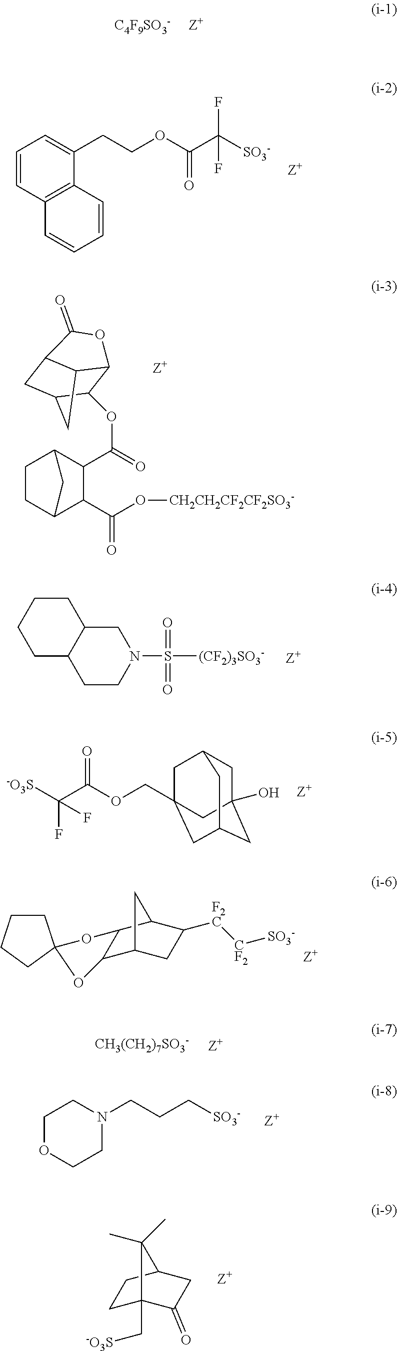

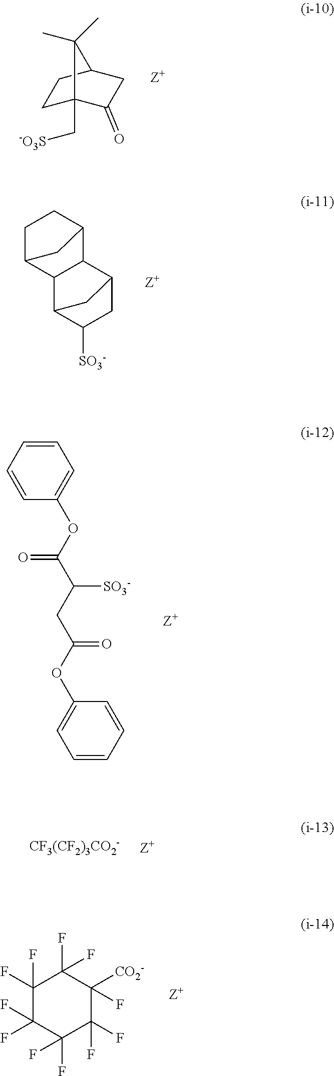

In the above formulae (i-1) to (i-14), Z⁺ represents the radiation-sensitive cation.

As the compound (B1), the compounds (i-1) to (i-14) are preferred.

The lower limit of the content of the compound (B1) with respect to 100 parts by mass of the polymer (A1) is preferably 0.1 parts by mass, more preferably 1 part by mass, still more preferably 5 parts by mass, particularly preferably 10 parts by mass, still more particularly preferably 15 parts by mass, and most preferably 20 parts by mass. The upper limit of the content of the compound (B1) is preferably 50 parts by mass, more preferably 40 parts by mass, still more preferably 35 parts by mass, and particularly preferably 30 parts by mass. When the content of the compound (B1) falls within the above range, the sensitivity of the radiation-sensitive resin composition can be further improved, thereby enabling the lithography characteristics to be further improved. One, or two or more types of the compound (B1) may be used.

### (B2) Compound

The compound (B2) generates upon an irradiation with a radioactive ray a carboxylic acid (hereinafter, may be also referred to as “acid (II-1)”) not capable of substantially dissociating the acid-labile group (a) under a condition involving the temperature T^{X}° C. for 1 min, a sulfonic acid (hereinafter, may be also referred to as “acid (II-2)”; and the acid (II-1) and the acid (II-2) may be collectively referred to as “acid (II)”) not capable of substantially dissociating the acid-labile group (a) under the condition involving the temperature T^{X}° C. for 1 min, or a combination thereof. Depending on the action of the acid (II) generated from the compound (B2) upon an irradiation with a radioactive ray, the acid-labile group (a) is not substantially dissociated even if heating is conducted by, for example, post exposure baking (PEB) or the like, at a temperature of T^{X}° C. falling within the range of 80° C. to 130° C. for 1 min.

Examples of the acid (II-1) include compounds corresponding to the acid (II) represented by the above formula (4-4), as well as a compound represented by the following formula (5-1), and the like.

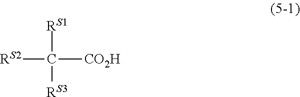

In the above formula (5-1), R^{S1}, R^{S2} and R^{S3} each independently represent a hydrogen atom or a monovalent organic group having 1 to 30 carbon atoms and not including a fluorine atom, or at least two of R^{S1}, R^{S2} and R^{S3} taken together represent a part of a ring structure having 3 to 20 ring atoms together with the carbon atom to which the at least two of R^{S1}, R^{S2} and R^{S3} bond.

Examples of the acid (II-2) include a compound represented by the following formula (5-2), and the like.

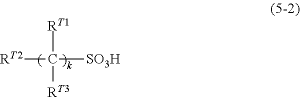

In the above formula (5-2), k is an integer of 0 to 10, wherein in a case in which k is 1, R^{T1} and R^{T3} each independently represent a monovalent organic group having 1 to 30 carbon atoms and not including a hydrogen atom or fluorine atom, or R^{T1} and R^{T3} taken together represent a part of a ring structure having 3 to 20 ring atoms together with the carbon atom to which R^{T1} and R^{T3} bond, and in a case in which k is no less than 2, a plurality of R^{T1}s are identical or different and represent a monovalent organic group having 1 to 30 carbon atoms and not including a hydrogen atom or fluorine atom, a plurality of R^{T3}s are identical or different and represent a monovalent organic group having 1 to 30 carbon atoms and not including a hydrogen atom or fluorine atom, or at least two of a plurality of R^{T1} and a plurality of R^{T2} taken together represent a part of a ring structure having 4 to 20 ring atoms together with the carbon chain to which the at least two of the plurality of R^{T1} and the plurality of R^{T2} bond; R^{T2} represents a substituted or unsubstituted monovalent chain hydrocarbon group having 1 to 10 carbon atoms, a substituted or unsubstituted monovalent alicyclic hydrocarbon group having 3 to 20 carbon atoms or a substituted or unsubstituted monovalent aromatic hydrocarbon group having 1 to 25 carbon atoms, wherein in a case in which k is 0 and R^{T2} represents a chain hydrocarbon group or an alicyclic hydrocarbon group, a fluorine atom does not bond to the carbon atom to which SO₃H in R^{T2} bonds, and in a case in which k is 0 and R^{T2} represents an aromatic hydrocarbon group, the aromatic hydrocarbon group does not have a fluorine atom.

It is preferred that R^{T1} and R^{T3} each represent a hydrogen atom.

Examples of the chain hydrocarbon group, the alicyclic hydrocarbon group and the aromatic hydrocarbon group which may be represented by R^{T2} include groups similar to those exemplified as R^{P} in the above formula (3), and the like.

Examples of the substituent for the chain hydrocarbon group, the alicyclic hydrocarbon group and the aromatic hydrocarbon group include a halogen atom, a hydroxy group, a nitro group, a keto group (═O), and the like.

It is preferred that the acid (II) is the acid (II-1).

The compound (B2) is typically a salt of a radiation-sensitive cation with an anion (hereinafter, may be also referred to as “anion (II)”) obtained by removing a proton from the acid group of the acid (II). The compound (B2) may have a betaine structure in which a group derived from the anion (II) such as a carboxylate group bonds to the hydrocarbon group or the like included in the radiation-sensitive cation.

In a light-exposed region, the compound (B2) gives the acid (II) from the anion (II) and a proton generated by decomposition of the radiation-sensitive cation through an action of a radioactive ray. This acid (II) is: a carboxylic acid (acid (II-1)) not capable of substantially dissociating the acid-labile group (a) under a condition of 130° C. for 1 min; or a sulfonic acid (acid (II-2)) in which a fluorine atom does not bond to a carbon atom adjacent to a sulfo group not capable of substantially dissociating the acid-labile group (a) under a condition at 90° C. for 1 min. Therefore, the compound (B2) serves as an acid diffusion control agent in the in the resist film.

The anion (II) is exemplified by a carboxylate anion that gives the acid (II-1), a sulfonate anion that gives the acid (II-2), and the like.

Examples of the radiation-sensitive cation in the compound (B2) include cations similar to those exemplified as the radiation-sensitive cations in the compound (B1), and the like.

Examples of the compound (B2) include compounds represented by the following formulae (ii-1) to (ii-6) (hereinafter, may be also referred to as “compounds (ii-1) to (ii-6)”), and the like.

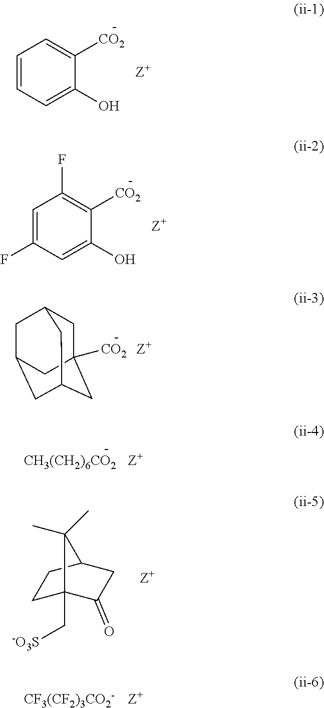

In the above formulae (ii-1) to (ii-6), Z⁺ represents a monovalent radiation-sensitive cation.

As the compound (B2), the compounds (ii-1) to (ii-6) are preferred.

The lower limit of the content of the compound (B2) with respect to 100 parts by mass of the polymer (A1) is preferably 0.1 parts by mass, more preferably 1 part by mass, still more preferably 2 parts by mass, and particularly preferably 4 parts by mass. The upper limit of the content of the compound (B2) is preferably 20 parts by mass, more preferably 10 parts by mass, still more preferably 8 parts by mass, and particularly preferably 6 parts by mass. When the content of the compound (B2) falls within the above range, the lithography characteristics of the radiation-sensitive resin composition can be further improved. One, or two or more types of the compound (B2) may be used.

### (C) Solvent

The radiation-sensitive resin composition typically contains the solvent (C). The solvent (C) is not particularly limited as long as it is a solvent capable of dissolving or dispersing at least the polymer (A1), the polymer (A2), the compound (B1) and the compound (B2), as well as the other optional component(s) which may be contained as desired.

The solvent (C) is exemplified by an alcohol solvent, an ether solvent, a ketone solvent, an amide solvent, an ester solvent, a hydrocarbon solvent, and the like.

Examples of the alcohol solvent include:

aliphatic monohydric alcohol solvents having 1 to 18 carbon atoms such as 4-methyl-2-pentanol and n-hexanol;

alicyclic monohydric alcohol solvents having 3 to 18 carbon atoms such as cyclohexanol;

polyhydric alcohol solvents having 2 to 18 carbon atoms such as 1,2-propylene glycol;

polyhydric alcohol partial ether solvents having 3 to 19 carbon atoms such as propylene glycol monomethyl ether; and the like.

Examples of the ether solvent include:

dialkyl ether solvents such as diethyl ether, dipropyl ether, dibutyl ether, dipentyl ether, diisoamyl ether, dihexyl ether and diheptyl ether;

cyclic ether solvents such as tetrahydrofuran and tetrahydropyran;

aromatic ring-containing ether solvents such as diphenyl ether and anisole; and the like.

Examples of the ketone solvent include:

chain ketone solvents such as acetone, methyl ethyl ketone, methyl n-propyl ketone, methyl n-butyl ketone, diethyl ketone, methyl iso-butyl ketone, 2-heptanone, ethyl n-butyl ketone, methyl n-hexyl ketone, di-iso-butyl ketone and trimethylnonanone;

cyclic ketone solvents such as cyclopentanone, cyclohexanone, cycloheptanone, cyclooctanone and methylcyclohexanone;

2,4-pentanedione, acetonylacetone and acetophenone; and the like.

Examples of the amide solvent include:

cyclic amide solvents such as N,N′-dimethylimidazolidinone and N-methylpyrrolidone;

chain amide solvents such as N-methylformamide, N,N-dimethylformamide, N,N-diethylformamide, acetamide, N-methylacetamide, N,N-dimethylacetamide and N-methylpropionamide; and the like.

Examples of the ester solvent include:

monocarboxylic acid ester solvents such as n-butyl acetate and ethyl lactate;

polyhydric alcohol carboxylate solvents such as propylene glycol acetate;

polyhydric alcohol partial ether carboxylate solvents such as propylene glycol monomethyl ether acetate;

polyhydric carboxylic acid diester solvents such as diethyl oxalate;

carbonate solvents such as dimethyl carbonate and diethyl carbonate; and the like.

Examples of the hydrocarbon solvent include:

aliphatic hydrocarbon solvents having 5 to 12 carbon atoms such as n-pentane and n-hexane;

aromatic hydrocarbon solvents having 6 to 16 carbon atoms such as toluene and xylene; and the like.

Of these, the ester solvent and/or the ketone solvent are/is preferred, the polyhydric alcohol partial ether carboxylate solvent and/or the cyclic ketone solvent are/is more preferred, and propylene glycol monomethyl ether acetate and/or cyclohexanone are/is still more preferred. One, or two or more types of the solvent (C) may be contained.

### Other Optional Components

The other optional component is exemplified by a basic compound, a surfactant, and the like. The radiation-sensitive resin composition may contain one, or two or more types of each of the other optional component.

Basic Compound

A basic compound controls a diffusion phenomenon of the acid generated from the compound (B1) and the like in the resist film upon exposure, similarly to the compound (B2), thereby serving to inhibit unwanted chemical reactions in a non-exposed region.

Examples of the basic compound include nitrogen-containing compounds, e.g., primary amines such as n-pentylamine; secondary amines such as di-n-pentylamine; tertiary amines such as tri-n-pentylamine; amide group-containing compounds such as N,N-dimethylacetamide and N-t-amyloxycarbonyl-4-hydroxypiperidine; urea compounds such as 1,1-dimethyl urea; nitrogen-containing heterocyclic compounds such as 2,6-di-i-propylaniline and N-(undecylcarbonyloxyethyl)morpholine; and the like.

In the case in which the radiation-sensitive resin composition contains the basic compound, the upper limit of the content of the basic compound with respect to 100 parts by mass of the polymer (A1) is preferably 10 parts by mass, and more preferably 7 parts by mass. The lower limit of the content of the basic compound is, for example, 0.1 parts by mass.

Surfactant

The surfactant exerts the effect of improving the coating property, striation, developability, and the like. Examples of the surfactant include: nonionic surfactants such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate and polyethylene glycol distearate; and the like. Examples of commercially available surfactants include KP341 (Shin-Etsu Chemical Co., Ltd.), Polyflow No. 75 and Polyflow No. 95 (both available from Kyoeisha Chemical Co., Ltd.), EFTOP EF301, EFTOP EF303 and EFTOP EF352 (all available from Tochem Products Co. Ltd.), Megaface F171 and Megaface F173 (all available from DIC Corporation), Fluorad FC430 and Fluorad FC431 (both available from Sumitomo 3M Limited), ASAHI GUARD AG710, Surflon S-382, Surflon SC-101, Surflon SC-102, Surflon SC-103, Surflon SC-104, Surflon SC-105 and Surflon SC-106 (all available from Asahi Glass Co., Ltd.), and the like.

In a case in which the radiation-sensitive resin composition contains the surfactant, the upper limit of the content of the surfactant with respect to 100 parts by mass of the polymer (A1) is preferably 2 parts by mass. The lower limit of the content is, for example, 0.1 parts by mass.

### Preparation Procedure of Radiation-Sensitive Resin Composition

The radiation-sensitive resin composition may be prepared, for example, by mixing the polymer (A1), the polymer (A2), the compound (B1), the compound (B2) and the solvent (C), as well as the other optional component which is added as needed, in a certain ratio, and preferably filtering a thus resulting mixture through a membrane filter having a pore size of about 200 nm. The lower limit of the solid content concentration of the radiation-sensitive resin composition is preferably 0.1% by mass, more preferably 0.5% by mass, still more preferably 1% by mass, and particularly preferably 1.5% by mass. The upper limit of the solid content concentration is preferably 50% by mass, more preferably 30% by mass, still more preferably 10% by mass, and particularly preferably 5% by mass.

The radiation-sensitive resin composition may be used either for positive-tone pattern formation conducted using an alkaline developer solution, or for negative-tone pattern formation conducted using an organic solvent-containing developer solution.

### Resist Pattern-Forming Method

The resist pattern-forming method according to a second embodiment of the present invention includes: a step of applying the radiation-sensitive resin composition according to the first embodiment of the invention directly or indirectly on at least one face side of a substrate (hereinafter, may be also referred to as “applying step”); a step of exposing the resist film formed by the applying step (hereinafter, may be also referred to as “exposing step”); and a step of developing the resist film exposed (hereinafter, may be also referred to as “developing step”).

The radiation-sensitive resin composition of the first embodiment of the present invention described above is used in the resist pattern-forming method, thus enabling formation of a resist pattern which, by virtue of an extensive exposure latitude, is accompanied by less LWR, high resolution, superior rectangularity of the cross-sectional shape, and fewer defects. Each step will be described below.

Applying Step

In this step, the radiation-sensitive resin composition according to the first embodiment of the invention is applied directly or indirectly on at least one face side of a substrate. Thus, a resist film is formed directly or indirectly on at least one face side of the substrate. The substrate is exemplified by a conventionally well-known substrate such as a silicon wafer, a wafer coated with silicon dioxide or aluminum, and the like. In addition, an organic or inorganic antireflective film disclosed in, for example, Japanese Examined Patent Application, Publication No. H6-12452, Japanese Unexamined Patent Application, Publication No. S59-93448, and the like may be provided on the substrate. An application procedure is exemplified by spin-coating, cast coating, roll-coating, and the like. After the application, prebaking (PB) may be carried out as needed for evaporating the solvent remaining in the coating film. The lower limit of the temperature for PB is preferably 60° C., and more preferably 80° C. The upper limit of the temperature for PB is preferably 140° C., and more preferably 120° C. The lower limit of the time period for PB is preferably 5 sec, and more preferably 10 sec. The upper limit of the time period for PB is preferably 600 sec, and more preferably 300 sec. The lower limit of the average thickness of the resist film formed is preferably 10 nm, and more preferably 20 nm. The upper limit of the average thickness is preferably 1,000 nm, and more preferably 500 nm.

Exposing Step

In this step, the resist film is exposed. This exposure is carried out by irradiation with an exposure light through a photomask (as the case may be, through a liquid immersion medium such as water). Examples of the exposure light include electromagnetic waves such as visible light rays, ultraviolet rays, far ultraviolet rays, extreme ultraviolet rays (EUV), X-rays and γ-rays; charged particle rays such as electron beams and α-rays, and the like, which may be selected in accordance with a line width of the intended pattern. Of these, far ultraviolet rays, EUV or electron beams are preferred; an ArF excimer laser beam (wavelength: 193 nm), a KrF excimer laser beam (wavelength: 248 nm), EUV or an electron beam is more preferred; an ArF excimer laser beam, EUV or an electron beam is still more preferred; and EUV or an electron beam is particularly preferred.

It is preferred that post exposure baking (PEB) is carried out after the exposure to promote dissociation of the acid-labile group included in the polymer (A1), etc. mediated by the acid generated from the compound (B1), etc. upon the exposure in exposed regions of the resist film. This PEB enables an increase in a difference in solubility of the resist film in a developer solution between the light-exposed regions and light-unexposed regions. The lower limit of the temperature for PEB is preferably 50° C., more preferably 80° C., and still more preferably 100° C. The upper limit of the temperature is preferably 180° C., and more preferably 130° C. The lower limit of the time period for PEB is preferably 5 sec, more preferably 10 sec, and still more preferably 30 sec. The upper limit of the time period is preferably 600 sec, more preferably 300 sec, and still more preferably 100 sec.

Developing Step

In this step, the resist film exposed is developed. Accordingly, formation of a predetermined resist pattern is enabled. After the development, washing with a rinse agent such as water or an alcohol and then drying is typical. The development procedure in the developing step may be carried out by either development with an alkali, or development with an organic solvent.

In the case of the development with an alkali, the developer solution for use in the development is exemplified by alkaline aqueous solutions prepared by dissolving at least one alkaline compound such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide (TMAH), pyrrole, piperidine, choline, 1,8-diazabicyclo-[5.4.0]-7-undecene, 1,5-diazabicyclo-[4.3.0]-5-nonene, etc., and the like. Of these, an aqueous TMAH solution is preferred, and a 2.38% by mass aqueous TMAH solution is more preferred.

In the case of the development with an organic solvent, the developer solution is exemplified by: an organic solvent such as a hydrocarbon solvent, an ether solvent, an ester solvent, a ketone solvent and an alcohol solvent; a solvent containing the organic solvent; and the like. Exemplary organic solvent includes one, or two or more types of the solvents exemplified as the solvent (E) for the radiation-sensitive resin composition, and the like. Of these, the ester solvent and/or the ketone solvent are/is preferred. The ester solvent is preferably an acetic acid ester solvent, and more preferably n-butyl acetate. The ketone solvent is preferably a chain ketone, and more preferably 2-heptanone. The lower limit of the content of the organic solvent in the developer solution is preferably 80% by mass, more preferably 90% by mass, still more preferably 95% by mass, and particularly preferably 99% by mass. Components other than the organic solvent in the organic solvent developer solution are exemplified by water, silicone oil, and the like.

Examples of the development procedure include: a dipping procedure in which the substrate is immersed for a given time period in the developer solution charged in a container; a puddle procedure in which the developer solution is placed to form a dome-shaped bead by way of the surface tension on the surface of the substrate for a given time period to conduct a development; a spraying procedure in which the developer solution is sprayed onto the surface of the substrate; a dynamic dispensing procedure in which the developer solution is continuously applied onto the substrate, which is rotated at a constant speed, while scanning with a developer solution-application nozzle at a constant speed; and the like.

Examples of the pattern to be formed by the resist pattern-forming method include a line-and-space pattern, a hole pattern and the like.

### EXAMPLES

Hereinafter, the present invention is explained in detail by way of Examples, but the present invention is not in any way limited to these Examples. Measuring methods for various types of physical properties are shown below.

Mw, Mn and Mw/Mn

The Mw and the Mn were determined by gel permeation chromatography (GPC) using GPC columns (“G2000 HXL”×2, “G3000 HXL”×1 and “G4000 HXL”×1, Tosoh Corporation) under the analytical conditions involving a flow rate of 1.0 mL/min, an elution solvent of tetrahydrofuran, a sample concentration of 1.0% by mass, an amount of injected sample of 100 μL, a column temperature of 40° C., and a differential refractometer as a detector, with mono-dispersed polystyrene as a standard. Furthermore, the dispersity index (Mw/Mn) was calculated from the results of the determination of the Mw and the Mn.

¹³C-NMR Analysis

An analysis for determining the proportion of each structural unit contained in each polymer (mol %) was performed by using a nuclear magnetic resonance apparatus (JEOL, Ltd., “JNM-ECX400”), with deuterated dimethyl sulfoxide as a measurement solvent.

### Synthesis of Polymer

Monomers used for synthesizing polymers are presented below. It is to be noted that in the following Synthesis Examples, unless otherwise specified particularly, “parts by mass” means a value, provided that the total mass of the monomers used was 100 parts by mass, and “mol %” means a value, provided that the total mol number of the monomers used was 100 mol %.

M-9, M-10, M-11 or M-12 was used as a compound that includes a large protecting group having a sterically bulky structure (ring structure having no less than 7 ring atoms); M-5, M-6, M-7, M-8 or M-13 was used as a compound that includes a small protecting group having a sterically small structure (ring structure having no greater than 6 ring atoms); and M-14, M-15, M-16, M-17 or M-18 was used as a compound that includes a polar group.

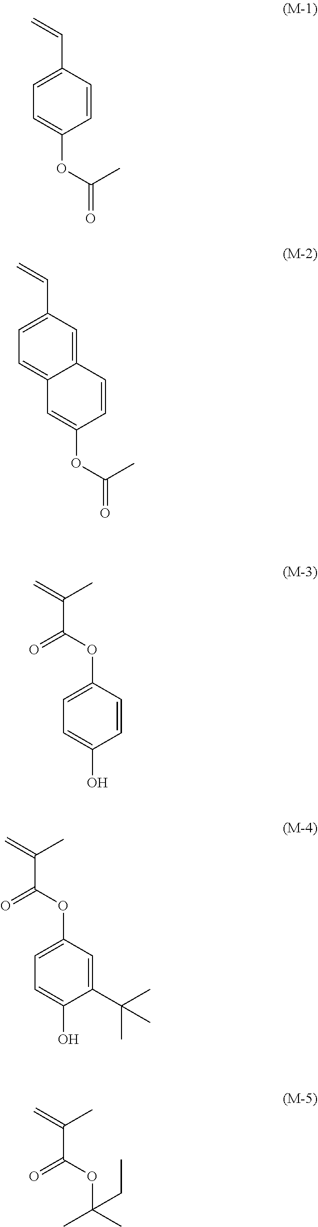 [SMILES: C=Cc1ccc(OC(C)=O)cc1 ; C=Cc1ccc2cc(OC(C)=O)ccc2c1 ; C=C(C)C(=O)Oc1ccc(O)cc1 ; C=C(C)C(=O)Oc1ccc(O)c(C(C)(C)C)c1 ; C=C(C)C(=O)OC(C)(C)CC]

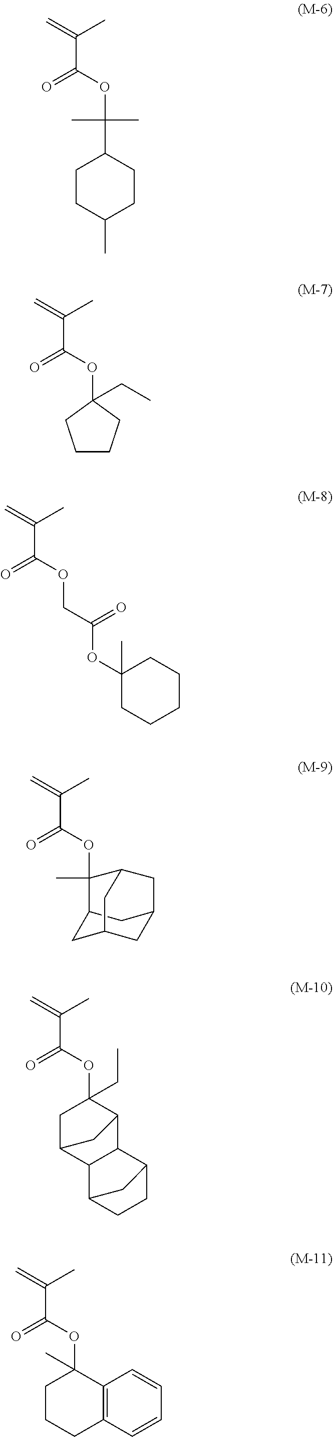 [SMILES: C=C(C)C(=O)OC(C)(C)C1CCC(C)CC1 ; C=C(C)C(=O)OC1(CC)CCCC1 ; C=C(C)C(=O)OCC(=O)OC1(C)CCCCC1 ; C=C(C)C(=O)OC1(C)C2CC3CC(C2)CC1C3 ; C=C(C)C(=O)OC1(CC)CC2CC1C1C3CCC(C3)C21 ; C=C(C)C(=O)OC1(C)CCCc2ccccc21]

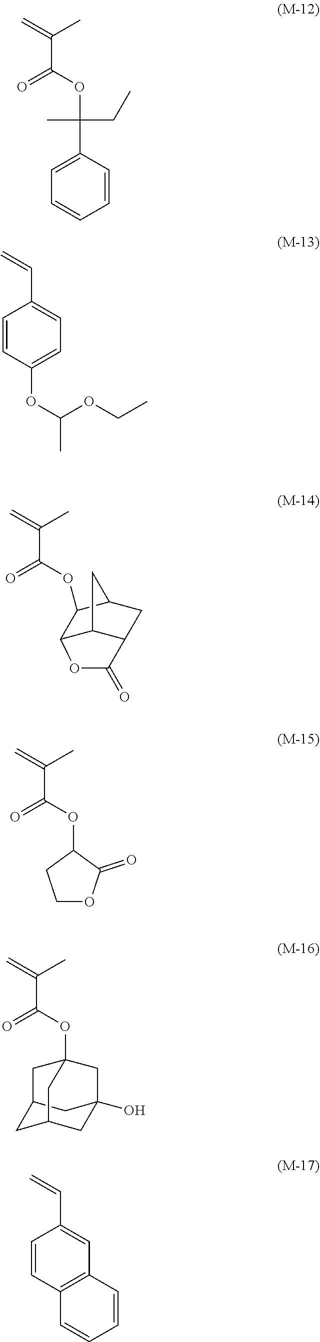 [SMILES: C=C(C)C(=O)OC(C)(CC)c1ccccc1 ; C=Cc1ccc(OC(C)OCC)cc1 ; C=C(C)C(=O)OC1C2CC3C(=O)OC1C3C2 ; C=C(C)C(=O)OC1CCOC1=O ; C=C(C)C(=O)OC12CC3CC(CC(O)(C3)C1)C2 ; C=Cc1ccc2ccccc2c1]

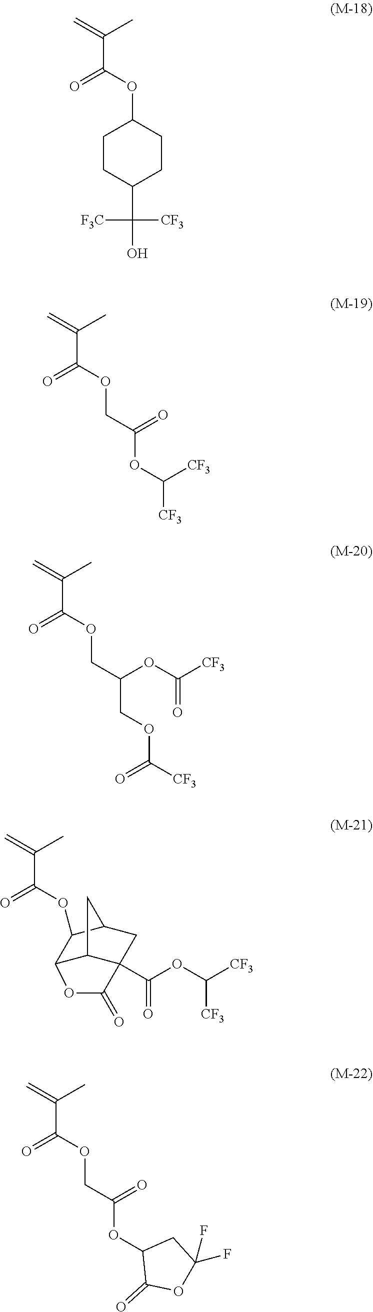 [SMILES: C=C(C)C(=O)OC1CCC(C(O)(C(F)(F)F)C(F)(F)F)CC1 ; C=C(C)C(=O)OCC(=O)OC(C(F)(F)F)C(F)(F)F ; C=C(C)C(=O)OCC(COC(=O)C(F)(F)F)OC(=O)C(F)(F)F ; C=C(C)C(=O)OC1C2CC3C1OC(=O)C3(C(=O)OC(C(F)(F)F)C(F)(F)F)C2 ; C=C(C)C(=O)OCC(=O)OC1CC(F)(F)OC1=O]

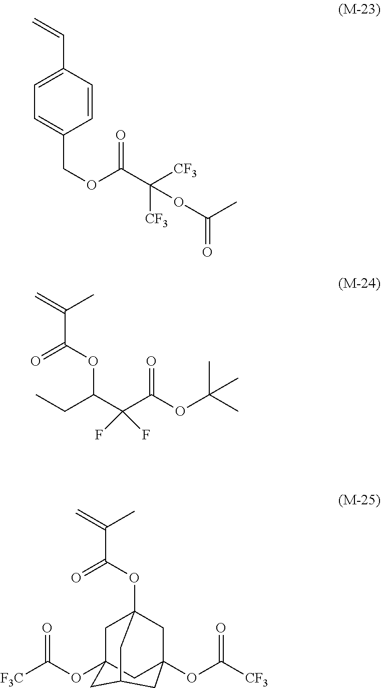 [SMILES: C=Cc1ccc(COC(=O)C(OC(C)=O)(C(F)(F)F)C(F)(F)F)cc1 ; C=C(C)C(=O)OC(CC)C(F)(F)C(=O)OC(C)(C)C ; C=C(C)C(=O)OC12CC3CC(OC(=O)C(F)(F)F)(C1)CC(OC(=O)C(F)(F)F)(C3)C2]

Synthesis of Polymer (A1)

### Synthesis Example 1: Synthesis of Polymer (Aa-1)

The compound (M-1) and the compound (M-5) as monomers were dissolved in 100 parts by mass of propylene glycol monomethyl ether such that the molar ratio was 50/50. A monomer solution was prepared by adding to a solution thus prepared, 6 mol % azobisisobutyronitrile (AIBN) as an initiator, and t-dodecyl mercaptan (38 parts by mass with respect to 100 parts by mass of the initiator) as a chain transfer agent. This monomer solution was maintained in a nitrogen atmosphere at a reaction temperature of 70° C. to permit polymerization for 16 hrs. After completion of the polymerization reaction, a resultant polymerization solution was added dropwise into 1,000 parts by mass of n-hexane, whereby the polymer was purified through solidification. To the polymer, 150 parts by mass of propylene glycol monomethyl ether were added. Furthermore, 150 parts by mass of methanol, triethylamine (1.5 molar equivalent with respect to the amount of the compound (M-1) used) and water (1.5 molar equivalent with respect to the amount of the compound (M-1) used) were added to the mixture. A hydrolysis reaction was allowed while the mixture was refluxed at a boiling point for 8 hrs. After completion of the reaction, the solvent and triethylamine were distilled off under reduced pressure, and a polymer thus obtained was dissolved in 150 parts by mass of acetone. This solution was added dropwise into 2,000 parts by mass of water to permit coagulation, and a produced white powder was filtered off and dried at 50° C. for 17 hrs to give a white powdery polymer (Aa-1) with a favorable yield. The Mw of the polymer (Aa-1) was 6,500, and the Mw/Mn thereof was 1.71. As a result of the ¹³C-NMR analysis, the proportions of the structural units derived from (M-1) and (M-5) were 50.3 mol % and 49.7 mol %, respectively.

### Synthesis Examples 2 to 4, 6 to 12 and 19 to 26: Syntheses of Polymers (Aa-2) to (Aa-4), (Aa-6) to (Aa-12) and (Aa-19) to (Aa-26)

Polymers (Aa-2) to (Aa-4), (Aa-6) to (Aa-12) and (Aa-19) to (Aa-26) were synthesized by a similar operation to Synthesis Example 1 except that each type of the monomer in the amount shown in Tables 1 and 2 below was used.

### Synthesis Example 5: Synthesis of Polymer (Aa-5)

The compound (M-4), the compound (M-13) and the compound (M-17) as monomers were dissolved in 100 parts by mass of propylene glycol monomethyl ether such that the molar ratio was 40/50/10. A monomer solution was prepared by adding to a solution thus prepared, 6 mol % AIBN as an initiator, and t-dodecyl mercaptan (38 parts by mass with respect to 100 parts by mass of the initiator) as a chain transfer agent. This monomer solution was maintained in a nitrogen atmosphere at a reaction temperature of 70° C. to permit polymerization for 16 hrs. After completion of the polymerization reaction, a resultant polymerization solution was added dropwise into 1,000 parts by mass of n-hexane, whereby the polymer was purified through solidification. A white powder was filtered off and dried at 50° C. for 17 hrs to give a white powdery polymer (Aa-5) with a favorable yield. The Mw of the polymer (Aa-5) was 6,800, and the Mw/Mn thereof was 1.69. As a result of the ¹³C-NMR analysis, the proportions of the structural units derived from (M-4), (M-13) and (M-17) were 39.9 mol %, 50.2 mol % and 9.9 mol %, respectively.

### Synthesis Examples 13 to 18 and Reference Example 1: Syntheses of Polymers (Aa-13) to (Aa-18) and (Ac-1)

Polymers (Aa-13) to (Aa-18) and (Ac-1) were synthesized by a similar operation to Synthesis Example 5 except that each type of the monomer in the amount shown in Table 1 below was used.

Values of the proportion, yield, Mw and Mw/Mn of each structural unit of the resultant polymer are shown together in Tables 1 and 2. It is to be noted that the denotation “-” in Tables 1 and 2 indicates that a corresponding component was not employed. M-1 and M-2 give a structural unit derived from hydroxystyrene and a structural unit derived from hydroxyvinylnaphthalene, respectively, through deacetylation by a hydrolysis treatment.

TABLE 1

| | | Monomer that gives | | | Monomer that gives | | | Monomer that gives | | | | | |
|---|---|---|---|---|---|---|---|---|---|---|---|---|---|
| | | structural unit (I) | | | structural unit (II) | | | other structural unit | | | | | |
| | | | | proportion | | | proportion | | | proportion | | | |
| | | | | of the | | | of the | | | of the | | | |
| | (A1) | | amount | structural | | amount | structural | | amount | structural | Yield | | |
| | Polymer | Type | (mol %) | unit (mol %) | type | (mol %) | unit (mol %) | Type | (mol %) | unit (mol %) | (%) | Mw | Mw/Mn |
| Synthesis | Aa-1 | M-1 | 50 | 50.3 | M-5 | 50 | 49.7 | — | — | — | 65 | 6,500 | 1.71 |
| Example 1 | | | | | | | | | | | | | |
| Synthesis | Aa-2 | M-2 | 40 | 40.1 | M-7 | 50 | 49.9 | M-16 | 10 | 10.0 | 64 | 6,400 | 1.67 |
| Example 2 | | | | | | | | | | | | | |
| Synthesis | Aa-3 | M-2 | 50 | 51.7 | M-8 | 40 | 39.2 | — | — | — | 62 | 6,300 | 1.65 |
| Example 3 | | | | | M-9 | 10 | 9.1 | | | | | | |
| Synthesis | Aa-4 | M-2 | 50 | 50.6 | M-12 | 50 | 49.4 | — | — | — | 65 | 6,500 | 1.66 |
| Example 4 | | | | | | | | | | | | | |
| Synthesis | Aa-5 | M-4 | 40 | 39.9 | M-13 | 50 | 50.2 | M-17 | 10 | 9.9 | 70 | 6,800 | 1.69 |
| Example 5 | | | | | | | | | | | | | |
| Synthesis | Aa-6 | M-2 | 60 | 61.5 | M-10 | 40 | 38.5 | — | — | — | 62 | 6,400 | 1.82 |
| Example 6 | | | | | | | | | | | | | |
| Synthesis | Aa-7 | M-1 | 40 | 40.2 | M-5 | 60 | 59.8 | — | — | — | 67 | 6,600 | 1.72 |
| Example 7 | | | | | | | | | | | | | |
| Synthesis | Aa-8 | M-1 | 30 | 31.5 | M-5 | 70 | 68.5 | — | — | — | 62 | 6,500 | 1.67 |
| Example 8 | | | | | | | | | | | | | |
| Synthesis | Aa-9 | M-1 | 30 | 32.0 | M-6 | 70 | 68.0 | — | — | — | 64 | 6,600 | 1.83 |
| Example 9 | | | | | | | | | | | | | |
| Synthesis | Aa-10 | M-1 | 40 | 40.5 | M-7 | 60 | 59.5 | — | — | — | 63 | 6,600 | 1.73 |
| Example 10 | | | | | | | | | | | | | |
| Synthesis | Aa-11 | M-1 | 30 | 30.8 | M-7 | 70 | 69.2 | — | — | — | 61 | 6,800 | 1.74 |
| Example 11 | | | | | | | | | | | | | |
| Synthesis | Aa-12 | M-1 | 25 | 26.2 | M-7 | 75 | 73.8 | — | — | — | 59 | 6,400 | 1.69 |
| Example 12 | | | | | | | | | | | | | |
| Synthesis | Aa-13 | M-3 | 40 | 42.1 | M-10 | 60 | 57.9 | — | — | — | 67 | 6,500 | 1.85 |
| Example 13 | | | | | | | | | | | | | |
| Synthesis | Aa-14 | M-3 | 40 | 41.5 | M-11 | 60 | 58.5 | — | — | — | 66 | 6,500 | 1.81 |
| Example 14 | | | | | | | | | | | | | |
| Synthesis | Aa-15 | M-4 | 30 | 31.1 | M-13 | 60 | 59.9 | M-16 | 10 | 9.0 | 64 | 6,800 | 1.69 |
| Example 15 | | | | | | | | | | | | | |
| Synthesis | Aa-16 | M-3 | 30 | 31.9 | M-10 | 40 | 38.9 | M-14 | 30 | 29.2 | 59 | 6,200 | 1.68 |
| Example 16 | | | | | | | | | | | | | |
| Synthesis | Aa-17 | M-3 | 30 | 32.3 | M-10 | 60 | 58.4 | M-14 | 10 | 9.3 | 57 | 6,300 | 1.59 |
| Example 17 | | | | | | | | | | | | | |
| Synthesis | Aa-18 | M-3 | 30 | 32.1 | M-10 | 60 | 58.2 | M-15 | 10 | 9.7 | 57 | 6,400 | 1.63 |
| Example 18 | | | | | | | | | | | | | |

TABLE 2

| | | Monomer that gives | | | Monomer that gives | | | Monomer that gives | | | | | |
|---|---|---|---|---|---|---|---|---|---|---|---|---|---|
| | | structural unit (I) | | | structural unit (II) | | | other structural unit | | | | | |
| | | | | proportion | | | proportion | | | proportion | | | |
| | | | | of the | | | of the | | | of the | | | |
| | (A1) | | amount | structural | | amount | structural | | amount | structural | Yield | | |
| | Polymer | type | (mol %) | unit (mol %) | type | (mol %) | unit (mol %) | Type | (mol %) | unit (mol %) | (%) | Mw | Mw/Mn |
| Synthesis | Aa-19 | M-1 | 40 | 40.6 | M-7 | 20 | 19.9 | — | — | — | 62 | 6,400 | 1.66 |
| Example 19 | | | | | M-8 | 40 | 39.5 | | | | | | |
| Synthesis | Aa-20 | M-1 | 40 | 41.7 | M-7 | 40 | 39.6 | — | — | — | 63 | 6,500 | 1.68 |
| Example 20 | | | | | M-9 | 20 | 18.7 | | | | | | |
| Synthesis | Aa-21 | M-1 | 40 | 40.0 | M-5 | 15 | 14.9 | — | — | — | 61 | 6,400 | 1.62 |
| Example 21 | | | | | M-7 | 45 | 45.1 | | | | | | |
| Synthesis | Aa-22 | M-1 | 40 | 40.3 | M-7 | 30 | 30.1 | — | — | — | 65 | 6,300 | 1.69 |
| Example 22 | | | | | M-12 | 30 | 29.6 | | | | | | |
| Synthesis | Aa-23 | M-1 | 30 | 29.9 | M-8 | 30 | 29.7 | — | — | — | 67 | 6,800 | 1.69 |
| Example 23 | | | | | M-13 | 40 | 40.4 | | | | | | |
| Synthesis | Aa-24 | M-1 | 40 | 41.0 | M-10 | 30 | 28.9 | — | — | — | 61 | 6,500 | 1.79 |
| Example 24 | | | | | M-12 | 30 | 30.1 | | | | | | |
| Synthesis | Aa-25 | M-1 | 35 | 36.4 | M-7 | 20 | 19.9 | M-16 | 5 | 4.5 | 64 | 6,400 | 1.68 |
| Example 25 | | | | | M-8 | 40 | 39.2 | | | | | | |
| Synthesis | Aa-26 | M-1 | 35 | 35.8 | M-7 | 20 | 20.0 | M-18 | 5 | 5.0 | 63 | 6,200 | 1.65 |
| Example 26 | | | | | M-8 | 40 | 39.2 | | | | | | |
| Reference | Ac-1 | — | — | — | M-7 | 50 | 50.4 | M-14 | 50 | 49.6 | 78 | 6,000 | 1.59 |
| Example 1 | | | | | | | | | | | | | |

Synthesis of Polymer (A2)

### Synthesis Example 27: Synthesis of Polymer (Ab-1)

The compound (M-7) and the compound (M-19) as monomers were dissolved in 100 parts by mass of cyclohexanone such that the molar ratio was 50/50. A monomer solution was prepared by adding 3 mol % AIBN as an initiator to a solution thus prepared. This monomer solution was maintained in a nitrogen atmosphere at a reaction temperature of 85° C. to permit polymerization for 6 hrs. After completion of the polymerization reaction, a resultant polymerization solution was added dropwise into 1,000 parts by mass of heptane/ethyl acetate (mass ratio: 8/2), whereby the polymer was purified through solidification, and a powder was filtered off. Subsequently, a solid obtained by the filtration was washed by rinsing with 300 parts by mass of heptane/ethyl acetate (mass ratio: 8/2). Thereafter, drying at 50° C. for 17 hrs gave a white powdery polymer (Ab-1) with a favorable yield. The Mw of the polymer (Ab-1) was 9,000, and the Mw/Mn thereof was 1.40. As a result of the ¹³C-NMR analysis, the proportions of the structural units derived from (M-7) and (M-19) were 49.7 mol % and 50.3 mol %, respectively.

### Synthesis Examples 28 to 42 and Reference Example 2: Syntheses of Polymers (Ab-2) to (Ab-16) and (Ac-2)

Polymers (Ab-2) to (Ab-16) and (Ac-2) were synthesized by a similar operation to Synthesis Example 27 except that each type of the monomer in the amount shown in Table 3 below was used.

Values of the proportion, yield, Mw and Mw/Mn of each structural unit of the resultant polymer are shown together in Table 3. It is to be noted that the denotation “-” in Table 3 indicates that a corresponding component was not employed.

TABLE 3

| | | Monomer that gives | | | Monomer that gives | | | Monomer that gives | | |
|---|---|---|---|---|---|---|---|---|---|---|
| | | structural unit (I) | | | structural unit (II) | | | structural unit (III) | | |
| | | | | proportion | | | proportion | | | proportion |
| | | | | of the | | | of the | | | of the |
| | (A2) | | amount | structural | | amount | structural | | amount | structural |
| | Polymer | type | (mol %) | unit (mol %) | type | (mol %) | unit (mol %) | type | (mol %) | unit (mol %) |
| Synthesis | Ab-1 | — | — | — | M-7 | 50 | 49.7 | M-19 | 50 | 50.3 |
| Example 27 | | | | | | | | | | |
| Synthesis | Ab-2 | — | — | — | M-7 | 40 | 40.0 | M-24 | 50 | 50.1 |
| Example 28 | | | | | | | | | | |
| Synthesis | Ab-3 | — | — | — | M-12 | 50 | 49.2 | M-25 | 50 | 50.8 |
| Example 29 | | | | | | | | | | |
| Synthesis | Ab-4 | — | — | — | M-8 | 40 | 39.5 | M-20 | 70 | 60.5 |
| Example 30 | | | | | | | | | | |
| Synthesis | Ab-5 | — | — | — | M-7 | 30 | 30.1 | M-21 | 70 | 69.9 |
| Example 31 | | | | | | | | | | |
| Synthesis | Ab-6 | — | — | — | M-7 | 30 | 30.2 | M-22 | 70 | 69.8 |
| Example 32 | | | | | | | | | | |
| Synthesis | Ab-7 | — | — | — | M-12 | 30 | 29.4 | M-23 | 70 | 70.6 |
| Example 33 | | | | | | | | | | |
| Synthesis | Ab-8 | — | — | — | M-7 | 30 | 29.8 | M-24 | 70 | 70.2 |
| Example 34 | | | | | | | | | | |
| Synthesis | Ab-9 | — | — | — | — | — | — | M-20 | 100 | 100 |
| Example 35 | | | | | | | | | | |
| Synthesis | Ab-10 | — | — | — | — | — | — | M-21 | 100 | 100 |
| Example 36 | | | | | | | | | | |
| Synthesis | Ab-11 | — | — | — | — | — | — | M-22 | 100 | 100 |
| Example 37 | | | | | | | | | | |
| Synthesis | Ab-12 | — | — | — | — | — | — | M-23 | 100 | 100 |
| Example 38 | | | | | | | | | | |
| Synthesis | Ab-13 | — | — | — | — | — | — | M-24 | 100 | 100 |
| Example 39 | | | | | | | | | | |
| Synthesis | Ab-14 | — | — | — | — | — | — | M-19 | 50 | 49.9 |
| Example 40 | | | | | | | | M-24 | 50 | 50.1 |
| Synthesis | Ab-15 | M-3 | 10 | 10.2 | — | — | — | M-25 | 90 | 89.8 |
| Example 41 | | | | | | | | | | |
| Synthesis | Ab-16 | — | — | — | — | — | — | M-19 | 90 | 90.4 |
| Example 42 | | | | | | | | | | |
| Reference | Ac-2 | — | — | — | — | — | — | — | — | — |
| Example 2 | | | | | | | | | | |

| | Monomer that gives | | | | | |
|---|---|---|---|---|---|---|
| | other structural unit | | | | | |
| | | | proportion | | | |
| | | | of the | | | |
| | | amount | structural | Yield | | |
| | type | (mol %) | unit (mol %) | (%) | Mw | Mw/Mn |
| Synthesis | — | — | — | 72 | 9,000 | 1.40 |
| Example 27 | | | | | | |
| Synthesis | M-18 | 10 | 9.9 | 69 | 11,000 | 1.55 |
| Example 28 | | | | | | |
| Synthesis | — | — | — | 76 | 7,000 | 1.43 |
| Example 29 | | | | | | |
| Synthesis | — | — | — | 74 | 9,100 | 1.61 |
| Example 30 | | | | | | |
| Synthesis | — | — | — | 78 | 8,400 | 1.53 |
| Example 31 | | | | | | |
| Synthesis | — | — | — | 79 | 7,100 | 1.57 |
| Example 32 | | | | | | |
| Synthesis | — | — | — | 71 | 7,500 | 1.49 |
| Example 33 | | | | | | |
| Synthesis | — | — | — | 74 | 8,200 | 1.50 |
| Example 34 | | | | | | |
| Synthesis | — | — | — | 80 | 8,000 | 1.58 |
| Example 35 | | | | | | |
| Synthesis | — | — | — | 81 | 7,800 | 1.43 |
| Example 36 | | | | | | |
| Synthesis | — | — | — | 79 | 7,900 | 1.42 |
| Example 37 | | | | | | |
| Synthesis | — | — | — | 78 | 8,200 | 1.49 |
| Example 38 | | | | | | |
| Synthesis | — | — | — | 80 | 8,000 | 1.50 |
| Example 39 | | | | | | |
| Synthesis | — | — | — | 78 | 9,700 | 1.57 |
| Example 40 | | | | | | |
| Synthesis | — | — | — | 72 | 7,700 | 1.59 |
| Example 41 | | | | | | |
| Synthesis | M-18 | 10 | 9.6 | 70 | 8,100 | 1.56 |
| Example 42 | | | | | | |
| Reference | M-18 | 100 | 100 | 70 | 8,500 | 1.49 |
| Example 2 | | | | | | |

Preparation of Radiation-Sensitive Resin Composition

Components other than the polymer (A1) and the polymer (A2) used for preparing the radiation-sensitive resin composition are shown below.

(B1) Compound

Each structural formula is as presented below.

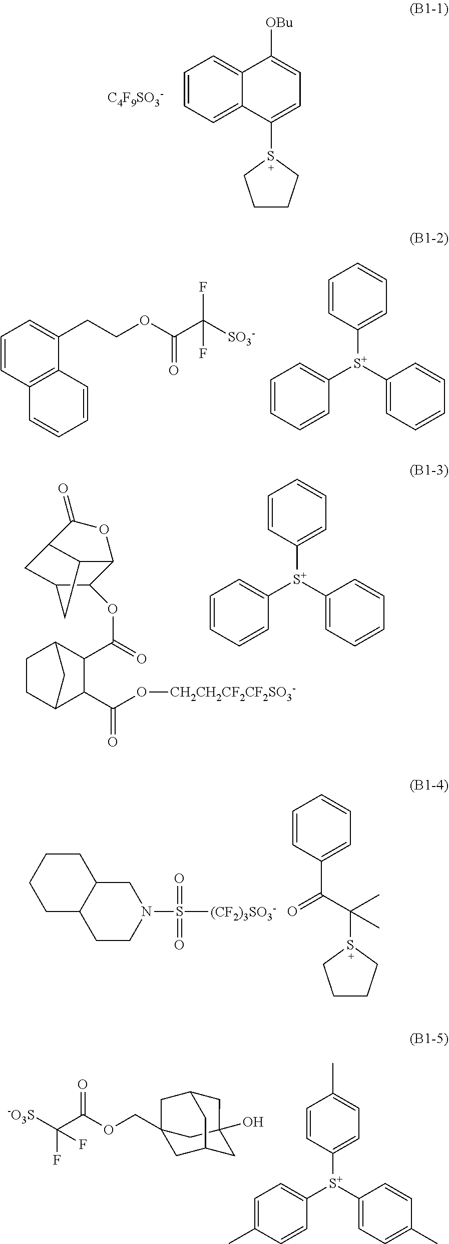

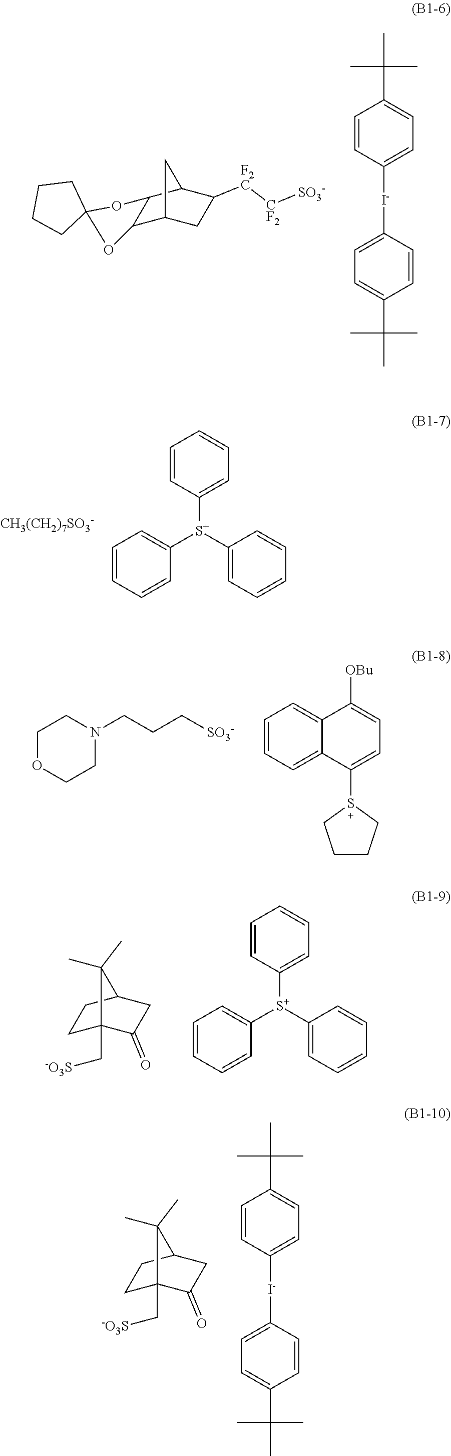

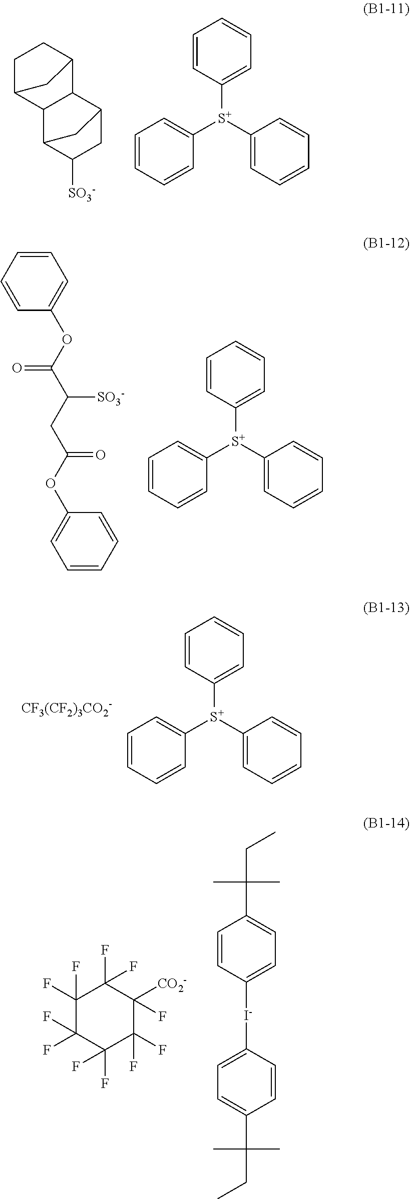

(B2) Compound

Each structural formula is as presented below.

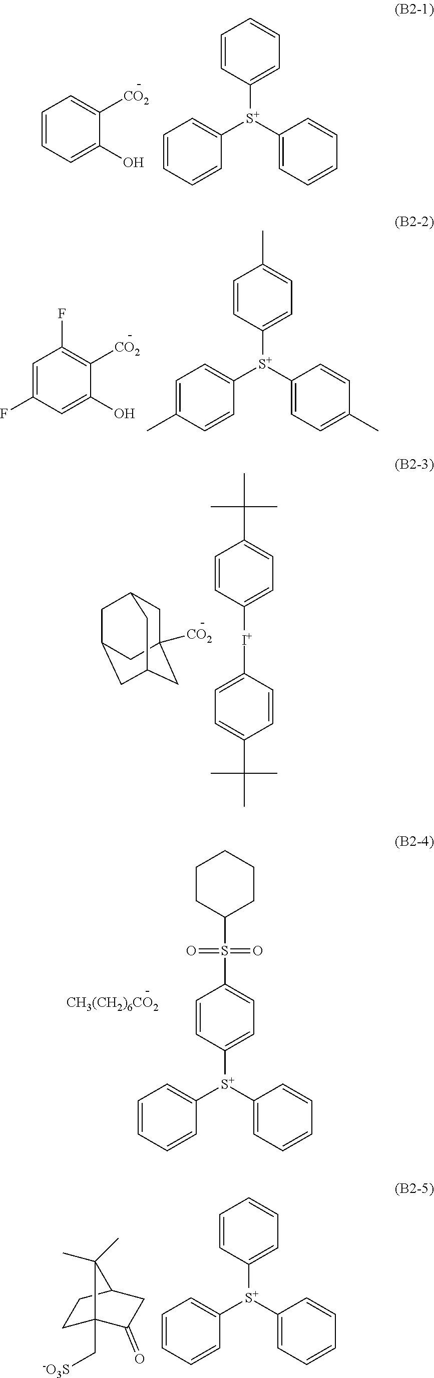

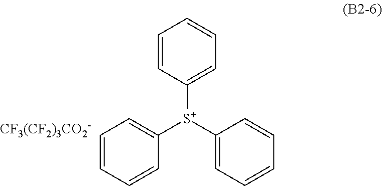 [SMILES: "CF3(CF2)3CO2-" ; c1ccc([S+](c2ccccc2)c2ccccc2)cc1]

(C) Solvent

C-1: propylene glycol monomethyl ether acetate

C-2: cyclohexanone

(D) Basic Compound

Each structural formula is as presented below.

D-1: 2,6-di-i-propylaniline

D-2: tri-n-pentylamine

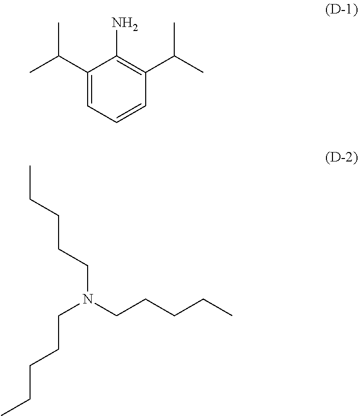

### Example 1

A radiation-sensitive resin composition (J-1) was prepared by mixing 100 parts by mass of (Aa-1) as the polymer (A1), 5 parts by mass of (Ab-1) as the polymer (A2), 10 parts by mass of (B1-1) as the compound (B1), 5 parts by mass of (B2-1) as the compound (B2), and 3,510 parts by mass of (C-1) and 1,510 parts by mass of (C-2) as the solvent (C); and filtering a resulting mixture through a membrane filter of 20 nm.

### Examples 2 to 32 and Comparative Examples 1 to 7

Radiation-sensitive resin compositions (J-2) to (J-32) and (CJ-1) to (CJ-7) were prepared by a similar operation to Example 1 except that each type of the monomer in the content shown in Tables 4 and 5 below was used. The denotation “-” in Tables 4 and 5 indicates that a corresponding component was not employed.

TABLE 4

| | | (A1) Polymer | | (A2) Polymer | | (B1) | | (B2) | | | | (D) Basic | |
|---|---|---|---|---|---|---|---|---|---|---|---|---|---|
| | Radiation- | | content | | content | Compound | | Compound | | (C) Solvent | | compound | |
| | sensitive | | (parts | | (parts | | content | | content | | content | | content |
| | resin | | by | | by | | (parts by | | (parts by | | (parts | | (parts |
| | composition | type | mass) | type | mass) | type | mass) | type | mass) | type | by mass) | type | by mass) |
| Example 1 | J-1 | Aa-1 | 100 | Ab-1 | 5 | B1-1 | 10 | B2-1 | 5 | C-1/C-2 | 3,510/1,510 | — | — |
| Example 2 | J-2 | Aa-2 | 100 | Ab-2 | 5 | B-2 | 15 | B2-2 | 5 | C-1/C-2 | 3,510/1,510 | — | — |
| Example 3 | J-3 | Aa-3 | 100 | Ab-3 | 5 | B1-3 | 25 | B2-3 | 5 | C-1/C-2 | 3.510/1,510 | — | — |
| Example 4 | J-4 | Aa-4 | 100 | Ab-4 | 5 | B1-4 | 25 | B2-4 | 5 | C-1/C-2 | 3,510/1,510 | — | — |
| Example 5 | J-5 | Aa-5 | 100 | Ab-5 | 5 | B1-5 | 25 | B2-1 | 5 | C-1/C-2 | 3,510/1,510 | — | — |
| Example 6 | J-6 | Aa-6 | 100 | Ab-6 | 5 | B1-6 | 25 | B2-1 | 5 | C-1/C-2 | 3,510/1,510 | — | — |
| Example 7 | J-7 | Aa-2 | 100 | Ab-7 | 5 | B1-2 | 15 | B2-1 | 5 | C-1/C-2 | 3,510/1,510 | — | — |
| | | | | | | B1-3 | 10 | | | | | | |
| Example 8 | J-8 | Aa-3 | 100 | Ab-8 | 5 | B1-2 | 15 | B2-1 | 5 | C-1/C-2 | 3,510/1,510 | — | — |
| | | | | | | B1-7 | 10 | | | | | | |
| Example 9 | J-9 | Aa-4 | 100 | Ab-9 | 5 | B1-6 | 15 | B2-2 | 5 | C-1/C-2 | 3,510/1,510 | — | — |
| | | | | | | B1-7 | 10 | | | | | | |
| Example 10 | J-10 | Aa-5 | 100 | Ab-10 | 5 | B1-10 | 25 | B2-2 | 5 | C-1/C-2 | 3,510/1,510 | — | — |
| Example 11 | J-11 | Aa-7 | 100 | Ab-1 | 5 | B1-1 | 25 | B2-1 | 5 | C-1/C-2 | 3,510/1,510 | — | — |
| Example 12 | J-12 | Aa-8 | 100 | Ab-2 | 5 | B1-2 | 25 | B2-2 | 5 | C-1/C-2 | 3,510/1,510 | — | — |
| Example 13 | J-13 | Aa-9 | 100 | Ab-3 | 5 | B1-3 | 25 | B2-3 | 5 | C-1/C-2 | 3,510/1,510 | — | — |
| Example 14 | J-14 | Aa-10 | 100 | Ab-4 | 5 | B1-4 | 25 | B2-3 | 5 | C-1/C-2 | 3,510/1,510 | — | — |
| Example 15 | J-15 | Aa-11 | 100 | Ab-5 | 5 | B1-5 | 25 | B2-3 | 5 | C-1/C-2 | 3,510/1,510 | — | — |
| Example 16 | J-16 | Aa-12 | 100 | Ab-6 | 5 | B1-6 | 25 | B2-3 | 5 | C-1/C-2 | 3,510/1,510 | — | — |
| Example 17 | J-17 | Aa-13 | 100 | Ab-7 | 5 | B1-3 | 15 | B2-3 | 5 | C-1/C-2 | 3,510/1,510 | — | — |
| | | | | | | B1-7 | 10 | | | | | | |
| Example 18 | J-18 | Aa-14 | 100 | Ab-8 | 5 | B1-3 | 15 | B2-3 | 5 | C-1/C-2 | 3,510/1,510 | — | — |
| | | | | | | B1-8 | 10 | | | | | | |
| Example 19 | J-19 | Aa-15 | 100 | Ab-9 | 5 | B1-3 | 15 | B2-3 | 5 | C-1/C-2 | 3,510/1,510 | — | — |
| | | | | | | B1-9 | 10 | | | | | | |
| Example 20 | J-20 | Aa-19 | 100 | Ab-10 | 5 | B1-3 | 15 | B2-3 | 5 | C-1/C-2 | 3,510/1,510 | — | — |
| | | | | | | B1-10 | 10 | | | | | | |

TABLE 5

| | | (A1) Polymer | | (A2) Polymer | | (B1) | | (B2) | | | | (D) Basic | |
|---|---|---|---|---|---|---|---|---|---|---|---|---|---|
| | Radiation- | | content | | content | Compound | | Compound | | (C) Solvent | | compound | |
| | sensitive | | (parts | | (parts | | content | | content | | content | | content |
| | resin | | by | | by | | (parts by | | (parts by | | (parts | | (parts |
| | composition | type | mass) | type | mass) | type | mass) | type | mass) | type | by mass) | type | by mass) |
| Example 21 | J-21 | Aa-20 | 100 | Ab-11 | 5 | B1-3 | 15 | B2-3 | 5 | C-1/C-2 | 3,510/1,510 | — | — |
| | | | | | | B1-11 | 10 | | | | | | |
| Example 22 | J-22 | Aa-21 | 100 | Ab-12 | 5 | B1-3 | 15 | B2-3 | 5 | C-1/C-2 | 3,510/1,510 | — | — |
| | | | | | | B1-12 | 10 | | | | | | |
| Example 23 | J-23 | Aa-22 | 100 | Ab-13 | 5 | B1-3 | 15 | B2-3 | 5 | C-1/C-2 | 3,510/1,510 | — | — |
| | | | | | | B1-13 | 10 | | | | | | |
| Example 24 | J-24 | Aa-23 | 100 | Ab-14 | 5 | B1-3 | 15 | B2-3 | 5 | C-1/C-2 | 3,510/1,510 | — | — |
| | | | | | | B1-14 | 10 | | | | | | |
| Example 25 | J-25 | Aa-24 | 100 | Ab-13 | 5 | B1-10 | 15 | B2-3 | 5 | C-1/C-2 | 3,510/1,510 | — | — |
| | | | | | | B1-11 | 10 | | | | | | |
| Example 26 | J-26 | Aa-25 | 100 | Ab-15 | 5 | B1-6 | 15 | B2-3 | 5 | C-1/C-2 | 3,510/1,510 | | |
| | | | | | | B1-7 | 10 | | | | | | |
| Example 27 | J-27 | Aa-26 | 100 | Ab-16 | 5 | B1-6 | 15 | B2-3 | 5 | C-1/C-2 | 3,510/1,510 | | |
| | | | | | | B1-8 | 10 | | | | | | |
| Example 28 | J-28 | Aa-16 | 100 | Ab-9 | 5 | B1-6 | 15 | B2-3 | 5 | C-1/C-2 | 3,510/1,510 | — | — |
| | | | | | | B1-7 | 10 | | | | | | |
| Example 29 | J-29 | Aa-17 | 100 | Ab-9 | 5 | B1-6 | 15 | B2-3 | 5 | C-1/C-2 | 3,510/1,510 | — | — |
| | | | | | | B1-7 | 10 | | | | | | |
| Example 30 | J-30 | Aa-18 | 100 | Ab-9 | 5 | B1-6 | 15 | B2-3 | 5 | C-1/C-2 | 3,510/1,510 | — | — |
| | | | | | | B1-7 | 10 | | | | | | |
| Example 31 | J-31 | Aa-11 | 100 | Ab-5 | 5 | B1-5 | 25 | B2-5 | 5 | C-1/C-2 | 3,510/1,510 | — | — |
| Example 32 | J-32 | Aa-11 | 100 | Ab-5 | 5 | B1-5 | 25 | B2-6 | 5 | C-1/C-2 | 3,510/1,510 | — | — |
| Comparative | CJ-1 | Aa-11 | 100 | Ab-5 | 5 | B1-5 | 25 | — | — | C-1/C-2 | 3,510/1,510 | D-1 | 5 |
| Example 1 | | | | | | | | | | | | | |
| Comparative | CJ-2 | Aa-11 | 100 | Ab-5 | 5 | B1-5 | 25 | — | — | C-1/C-2 | 3,510/1,510 | D-2 | 5 |
| Example 2 | | | | | | | | | | | | | |
| Comparative | CJ-3 | Aa-11 | 100 | — | — | B1-5 | 25 | B2-3 | 5 | C-1/C-2 | 3,510/1,510 | — | — |
| Example 3 | | | | | | | | | | | | | |
| Comparative | CJ-4 | Aa-11 | 100 | Ac-2 | 5 | B1-5 | 25 | B2-3 | 5 | C-1/C-2 | 3,510/1,510 | — | — |
| Example 4 | | | | | | | | | | | | | |
| Comparative | CJ-5 | Aa-11 | 100 | — | — | B1-5 | 25 | — | — | C-1/C-2 | 3,510/1,510 | D-1 | 5 |
| Example 5 | | | | | | | | | | | | | |
| Comparative | CJ-6 | Ac-1 | 100 | Ab-5 | 5 | B1-5 | 25 | B2-3 | 5 | C-1/C-2 | 3,510/1,510 | — | — |
| Example 6 | | | | | | | | | | | | | |
| Comparative | CJ-7 | Ac-1 | 100 | — | — | B1-5 | 25 | B2-3 | 5 | C-1/C-2 | 3,510/1,510 | — | — |
| Example 7 | | | | | | | | | | | | | |

Resist Pattern Formation (1): Exposure to Electron Beam, Development with Alkali

The radiation-sensitive resin composition prepared as described above was applied on the surface of an 8-inch silicon wafer by using a spin coater (Tokyo Electron Limited, “CLEAN TRACK ACT8”), and subjected to PB at 110° C. for 60 sec. Cooling at 23° C. for 30 sec gave a resist film having an average film thickness of 50 nm. Next, this resist film was irradiated with an electron beam using a simplified electron beam writer (Hitachi, Ltd., “HL800D”; power: 50 KeV, electric current density: 5.0 A/cm²). After the irradiation, PEB was carried out at a PEB temperature shown in Table 6 for 60 sec. Thereafter, a development was carried out using a 2.38% by mass aqueous TMAH solution as an alkaline developer solution at 23° C. for 60 sec, followed by washing with water and drying to form a positive-tone resist pattern.

### Evaluations

The radiation-sensitive resin compositions were evaluated on the LWR performance, the resolution, rectangularity of the cross-sectional shape, the exposure latitude and the inhibitory ability of defects according to the following determination procedures, with respect to the resist patterns formed as described above. The results of the evaluations are shown in Table 6. A scanning electron microscope (Hitachi High-Technologies Corporation, “S-9380”) was used for the line-width measurement of the resist pattern. It is to be noted that an exposure dose at which a line width of 100 nm (L/S=1/1) was provided in forming the resist pattern was defined as an optimum exposure dose.

LWR Performance

The resist pattern formed as described above having a line width of 100 nm (L/S=1/1) was observed from above by using the scanning electron microscope. The line width was measured at arbitrary points of 50 in total, then a 3 Sigma value was determined from distribution of the measurements, and the value was defined as “LWR performance (nm)”. The value being smaller reveals less variance of the line width, indicating better LWR performance. The LWR performance may be evaluated to be: “favorable” in a case of being no greater than 20 nm; and “unfavorable” in a case of being greater than 20 nm.

Resolution

A dimension of the minimum resist pattern which was resolved at the optimum exposure dose was measured, and the measurement value was defined as “resolution (nm)”. The value being smaller reveals successful formation of a finer pattern, indicating a better resolution. The resolution may be evaluated to be: “favorable” in a case of being no greater than 60 nm; and “unfavorable” in a case of being greater than 60 nm.

Rectangularity of Cross-Sectional Shape

A cross-sectional shape of the resist pattern which was resolved at the optimum exposure dose described above was observed to measure a line width Lb at the middle along an altitude direction of the resist pattern, and a line width La at the top of the resist pattern. Then, an La/Lb value was calculated, and the calculated value was employed as a marker for the rectangular configuration of the cross-sectional shape. The rectangularity of the cross-sectional shape may be evaluated to be: “favorable” in a case of 0.9≤(La/Lb)≤1.1; and to be “unfavorable” in a case of (La/Lb)≤0.9, or 1.1≤(La/Lb).

Exposure Latitude

An exposure dose was altered stepwise by 1 μC/cm² within an exposure dose range including the optimum exposure dose, and a resist pattern was formed at each exposure dose. The line width of each resist pattern was measured using the scanning electron microscope. The exposure dose E (110) at which the line width of 110 nm was attained and the exposure dose E (90) at which the line width of 90 nm was attained were determined from the relationship between the line width obtained and the exposure dose, and the exposure latitude (%) was calculated using the following equation: exposure latitude=[E(110)−E(90)]100/(optimum exposure dose). The “exposure latitude” value being greater indicates less variation of the dimension of the formed pattern with a variation of the exposure dose, leading to a higher process yield in the production of devices. The exposure latitude may be evaluated to be: “favorable” in a case of being no less than 20%; and to be “unfavorable” in a case of being less than 20%.

Inhibitory Ability of Defects

The radiation-sensitive resin composition prepared as described above was applied on a substrate that is an 8-inch silicon wafer on which an antireflective film having an average thickness of 60 nm (Brewer Science, Inc., “DUV44”) had been provided, and subjected to PB at 110° C. for 60 sec. Cooling at 23° C. for 30 sec gave a resist film having an average film thickness of 50 nm. This resist film was subjected to a checkered flag exposure (exposure conditions: NA=0.68, σ=0.75, 25 mJ) on an entire surface of the wafer such that an area of 15 mm square was exposed alternately to provide light-exposed regions and non-light-exposed regions in an open frame, using a KrF excimer laser scanner (NIKON Corporation, “NSR-S203B”; wavelength: 248 nm). After the irradiation, baking was carried out at a PEB temperature shown in Table 6 for 60 sec. Then a development was carried out using a 2.38% by mass aqueous TMAH solution as an alkaline developer solution at 23° C. for 60 sec, followed by washing with water and drying.

A defect number upon development was measured by a defect inspection apparatus (KLA-Tencor Corporation, “KLA-2351”) on the wafer thus patterned. The conditions employed for the measurement were as follows: inspection area=162 cm² in total; pixel size=0.25 μm; threshold=30; inspection light=visible light. An evaluation was made based on a value of the defect number derived by dividing the measured number by the inspection area (number/cm²). The value being smaller indicates a more favorable inhibitory ability of defects. The inhibitory ability of defects was evaluated in terms of the defect number to be: “A” in a case of being less than 1.0/cm²; “B” in a case of being no less than 1.0/cm² and less than 3.0/cm²; “C” in a case of being no less than 3.0/cm² and less than 10.0/cm²; and “D” in a case of being no less than 10.0/cm².

TABLE 6

| | Radiation- | | | | Rectangularity | | |
|---|---|---|---|---|---|---|---|
| | sensitive | PEB | LWR | | of cross- | Exposure | Inhibitory |
| | resin | temperature | performance | Resolution | sectional | latitude | ability of |
| | composition | (° C.) | (nm) | (nm) | shape | (%) | defects |
| Example 1 | J-1 | 110 | 18.2 | 57 | 0.93 | 24.3 | B |
| Example 2 | J-2 | 110 | 17.3 | 54 | 1.06 | 22.8 | B |
| Example 3 | J-3 | 110 | 17.5 | 58 | 0.91 | 23.1 | B |
| Example 4 | J-4 | 110 | 17.9 | 57 | 1.07 | 21.9 | A |
| Example 5 | J-5 | 110 | 18.5 | 56 | 1.09 | 22.4 | A |
| Example 6 | J-6 | 110 | 17.4 | 54 | 0.92 | 22.7 | A |
| Example 7 | J-7 | 110 | 18.1 | 58 | 0.94 | 23.3 | A |
| Example 8 | J-8 | 110 | 17.8 | 53 | 1.06 | 24.7 | A |
| Example 9 | J-9 | 110 | 17.1 | 54 | 1.08 | 22.2 | A |
| Example 10 | J-10 | 130 | 16.2 | 52 | 0.93 | 21.4 | A |
| Example 11 | J-11 | 110 | 13.9 | 49 | 0.96 | 26.4 | B |
| Example 12 | J-12 | 110 | 14.6 | 46 | 0.97 | 27.6 | B |
| Example 13 | J-13 | 110 | 14.5 | 48 | 1.03 | 28.8 | B |
| Example 14 | J-14 | 110 | 14.1 | 47 | 1.01 | 26.5 | A |
| Example 15 | J-15 | 110 | 13.7 | 44 | 0.99 | 28.1 | A |
| Example 16 | J-16 | 110 | 14.4 | 45 | 1.04 | 27.0 | A |
| Example 17 | J-17 | 110 | 15.1 | 51 | 0.94 | 24.6 | A |
| Example 18 | J-18 | 110 | 16.2 | 50 | 1.07 | 23.9 | A |
| Example 19 | J-19 | 110 | 14.1 | 47 | 1.03 | 27.1 | A |
| Example 20 | J-20 | 110 | 13.5 | 43 | 0.96 | 28.4 | A |
| Example 21 | J-21 | 110 | 16.8 | 54 | 0.93 | 24.0 | A |
| Example 22 | J-22 | 110 | 13.3 | 44 | 1.04 | 27.9 | A |
| Example 23 | J-23 | 110 | 15.3 | 54 | 0.93 | 24.4 | A |
| Example 24 | J-24 | 110 | 16.8 | 56 | 0.91 | 23.2 | A |
| Example 25 | J-25 | 130 | 18.2 | 52 | 1.07 | 24.0 | A |
| Example 26 | J-26 | 110 | 14.7 | 48 | 0.95 | 25.5 | A |
| Example 27 | J-27 | 110 | 14.0 | 45 | 1.04 | 27.7 | A |
| Example 28 | J-28 | 110 | 18.8 | 57 | 0.92 | 22.2 | A |
| Example 29 | J-29 | 110 | 16.2 | 55 | 0.93 | 23.7 | A |
| Example 30 | J-30 | 110 | 15.5 | 53 | 0.94 | 23.9 | A |
| Example 31 | J-31 | 85 | 13.8 | 46 | 0.96 | 28.2 | A |
| Example 32 | J-32 | 85 | 13.5 | 44 | 1.02 | 28.0 | A |
| Comparative | CJ-1 | 110 | 25.8 | 64 | 0.86 | 18.4 | C |
| Example 1 | | | | | | | |
| Comparative | CJ-2 | 85 | 27.5 | 65 | 1.15 | 19.0 | C |
| Example 2 | | | | | | | |
| Comparative | CJ-3 | 110 | 26.7 | 66 | 1.13 | 18.8 | D |
| Example 3 | | | | | | | |
| Comparative | CJ-4 | 110 | 24.0 | 63 | 0.88 | 19.2 | C |
| Example 4 | | | | | | | |
| Comparative | CJ-5 | 110 | 28.1 | 71 | 1.21 | 15.2 | D |
| Example 5 | | | | | | | |
| Comparative | CJ-6 | 110 | 33.1 | 73 | 1.22 | 13.1 | B |
| Example 6 | | | | | | | |
| Comparative | CJ-7 | 110 | 33.2 | 75 | 1.23 | 12.9 | B |
| Example 7 | | | | | | | |

From the results shown in Table 6, the radiation-sensitive resin compositions of the Examples were revealed to be superior in the LWR performance, the resolution, the rectangularity of the cross-sectional shape, the exposure latitude and the inhibitory ability of defects. Meanwhile, the radiation-sensitive resin compositions of the Comparative Examples were all revealed to be inferior in the performances as compared with those of the Examples. It has been known in general that exposure to an electron beam exhibits a similar tendency to that in the case of exposure to EUV. Therefore, also in the case of the exposure to EUV, superior lithography characteristics are expected according to the radiation-sensitive resin compositions of the Examples of the present invention.

Resist Pattern Formation (2): Exposure to EUV, Development with Alkali

Each radiation-sensitive resin composition shown in Tables 4 and 5 above was spin-coated on a Si substrate provided with a silicon-containing spin-on hard mask SHB-A940 (silicon content: 43% by mass) having an average thickness of 20 nm. Prebaking was carried out at 105° C. for 60 sec by using a hot plate to produce a resist film having an average thickness of 60 nm. The resist film was subjected to exposure by using an EUV scanner “NXE3300” manufactured by ASML Co., (NA=0.33; σ=0.9/0.6; quadrupole illumination, with a hole pattern mask having a pitch of 46 nm, +20% bias in terms of the dimension on the wafer). PEB was carried out at a temperature shown in Table 7 for 60 sec on a hot plate, and then a development was carried out using a 2.38% by mass aqueous TMAH solution for 30 sec, whereby a hole pattern having a dimension of 23 nm was obtained.

### Evaluations

The resist pattern thus obtained was evaluated as follows.

CDU Performance

A line-width measurement SEM (CG5000) manufactured by Hitachi High-Technologies Corporation was used to determine an exposure dose when holes with a hole dimension of 23 nm were formed, and the sensitivity was defined thereby. Dimensions of 50 holes were measured to determine CDU (dimension variance 3σ) (nm). The results are shown in Table 7. The value being smaller indicates a more favorable CDU performance, revealing less variance of the hole diameters in greater ranges. The CDU performance may be evaluated to be: “favorable” in a case of being no greater than 3.0 nm; and “unfavorable” in a case of being greater than 3.0 nm.

TABLE 7

| | Radiation- | | |
|---|---|---|---|
| | sensitive | PEB | CDU |
| | resin | temperature | performance |
| | composition | (° C.) | (nm) |
| Example 1 | J-1 | 110 | 2.9 |
| Example 2 | J-2 | 110 | 2.7 |
| Example 3 | J-3 | 110 | 2.8 |
| Example 4 | J-4 | 110 | 2.7 |
| Example 5 | J-5 | 110 | 2.9 |
| Example 6 | J-6 | 110 | 2.6 |
| Example 7 | J-7 | 110 | 2.9 |
| Example 8 | J-8 | 110 | 2.8 |
| Example 9 | J-9 | 110 | 2.8 |
| Example 10 | J-10 | 130 | 2.6 |
| Example 11 | J-11 | 110 | 2.3 |
| Example 12 | J-12 | 110 | 2.4 |
| Example 13 | J-13 | 110 | 2.4 |
| Example 14 | J-14 | 110 | 2.3 |
| Example 15 | J-15 | 110 | 2.3 |
| Example 16 | J-16 | 110 | 2.4 |
| Example 17 | J-17 | 110 | 2.5 |
| Example 18 | J-18 | 110 | 2.6 |
| Example 19 | J-19 | 110 | 2.4 |
| Example 20 | J-20 | 110 | 2.3 |
| Example 21 | J-21 | 110 | 2.6 |
| Example 22 | J-22 | 110 | 2.2 |
| Example 23 | J-23 | 110 | 2.6 |
| Example 24 | J-24 | 110 | 2.6 |
| Example 25 | J-25 | 130 | 2.7 |
| Example 26 | J-26 | 110 | 2.4 |
| Example 27 | J-27 | 110 | 2.4 |
| Example 28 | J-28 | 110 | 2.8 |
| Example 29 | J-29 | 110 | 2.7 |
| Example 30 | J-30 | 110 | 2.6 |
| Example 31 | J-31 | 85 | 2.3 |
| Example 32 | J-32 | 85 | 2.3 |
| Comparative | | | |
| Example 1 | CJ-1 | 110 | 3.2 |
| Comparative | | | |
| Example 2 | CJ-2 | 85 | 3.3 |
| Comparative | | | |
| Example 3 | CJ-3 | 110 | 3.6 |
| Comparative | | | |
| Example 4 | CJ-4 | 110 | 3.5 |
| Comparative | | | |
| Example 5 | CJ-5 | 110 | 3.7 |
| Comparative | CJ-6 | 110 | 3.8 |
| Example 6 | | | |
| Comparative | CJ-7 | 110 | 3.8 |
| Example 7 | | | |

As is clear from the results shown in Table 7, the radiation-sensitive resin compositions of the Examples were all superior in the CDU performance upon the EUV exposure.

Obviously, numerous modifications and variations of the present invention are possible in light of the above teachings. It is therefore to be understood that within the scope of the appended claims, the invention may be practiced otherwise than as specifically described herein.

What is claimed is:

1. A radiation-sensitive resin composition comprising:
a first polymer comprising a first structural unit that comprises a phenolic hydroxy group, and a second structural unit that comprises an acid-labile group;
a second polymer comprising a fluorine atom, a silicon atom, or both, and comprising a third structural unit that comprises an alkali-labile group;
a first compound that generates upon an irradiation with a radioactive ray an acid capable of dissociating the acid-labile group within 1 minute under a temperature T^{X}° C. of no less than 80° C. and no greater than 130° C.; and
a second compound that generates upon an irradiation with a radioactive ray a carboxylic acid, a sulfonic acid, or both, the carboxylic acid and the sulfonic acid each being not capable of substantially dissociating the acid-labile group within 1 minute under the temperature T^{X}° C.

2. The radiation-sensitive resin composition according to claim 1, wherein the acid generated from the second compound is a carboxylic acid.

3. The radiation-sensitive resin composition according to claim 1, wherein the third structural unit of the second polymer comprises a group represented by formula (1): 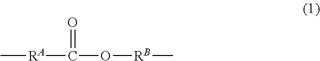
wherein, in the formula (1), R^{A} represents a single bond, a methanediyl group or a fluorinated methanediyl group; and R^{B} represents a single bond, a methanediyl group, a fluorinated methanediyl group, an ethanediyl group or a fluorinated ethanediyl group, or R^{A} and R^{B} taken together represent an aliphatic heterocyclic structure having 4 to 20 ring atoms together with —COO— to which R^{A} and R^{B} bond, wherein at least one of R^{A} or R^{B} comprises a fluorine atom.

4. The radiation-sensitive resin composition according to claim 1, wherein a content of the third structural unit in the second polymer is greater than 55 mol %.

5. The radiation-sensitive resin composition according to claim 1, wherein a content of the second structural unit in the first polymer is no less than 55 mol %.

6. The radiation-sensitive resin composition according to claim 1, wherein the acid-labile group included in the second structural unit of the first polymer is represented by at least one of formula (2-1) or formula (2-2): 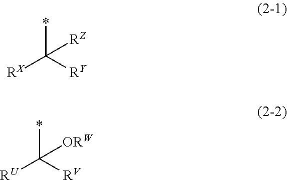
wherein,
in the formula (2-1), R^{X} represents a monovalent hydrocarbon group having 1 to 20 carbon atoms; and R^{Y} and R^{Z} each independently represent a monovalent chain hydrocarbon group having 1 to 6 carbon atoms or a monovalent alicyclic hydrocarbon group having 3 to 6 carbon atoms, or R^{Y} and R^{Z} taken together represent a monocyclic alicyclic structure having 3 to 6 ring atoms together with the carbon atom to which R^{Y} and R^{Z} bond, and
in the formula (2-2), R^{U} represents a hydrogen atom or a monovalent hydrocarbon group having 1 to 20 carbon atoms; and R^{V} and R^{W} each independently represent a monovalent chain hydrocarbon group having 1 to 6 carbon atoms or a monovalent alicyclic hydrocarbon group having 3 to 6 carbon atoms, or at least two of R^{U}, R^{V} and R^{W} taken together represent a monocyclic ring structure having 4 to 6 ring atoms together with the carbon atom or C—O to which the at least two of R^{U}, R^{V} and R^{W} bond.

7. The radiation-sensitive resin composition according to claim 6, wherein the second structural unit of the first polymer is represented by at least one of formulae (2-1A), (2-1B), (2-2A) or (2-2B): 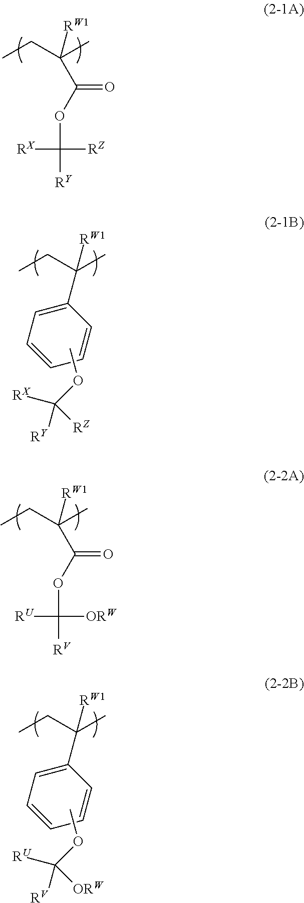
wherein, in the formulae (2-1A), (2-1B), (2-2A) and (2-2B), R^{X}, R^{Y} and R^{Z} are as defined in the formula (2-1); R^{U}, R^{V} and R^{W} are as defined in the formula (2-2); and R^{W1}s each independently represent a hydrogen atom, a fluorine atom, a methyl group or a trifluoromethyl group.

8. The radiation-sensitive resin composition according to claim 1, wherein the first polymer further comprises a fourth structural unit that comprises a lactone structure, a cyclic carbonate structure, a sultone structure or a combination thereof, and a content of the fourth structural unit in the first polymer is less than 40 mol %.

9. A resist pattern-forming method comprising:
applying the radiation-sensitive resin composition according to claim 1 directly or indirectly on at least one face side of a substrate to form a resist film;
exposing the resist film to an extreme ultraviolet ray or an electron beam; and
developing the resist film exposed.
